(19) United States
(12) Patent Application Publication
(10) Pub. No.: US 2017/0019170 A1
(43) Pub. Date: Jan. 19, 2017

(54) Dual-Directional Electro-Optic Probe

(71) Applicant: KEYSIGHT TECHNOLOGIES, INC., Santa Rosa, CA (US)

(72) Inventor: Gregory S. Lee, Mountain View, CA (US)

(21) Appl. No.: 15/124,027

(22) PCT Filed: Mar. 7, 2014
(86) PCT No.: PCT/US14/21788

§ 371 Date: Sep. 6, 2016

(51) Int. Cl. H04B 10/073; H04B 10/11; G01R 1/07; G01R 27/32; G01R 1/067

(52) U.S. Cl. CPC H04B 10/0731; G01R 27/32; G01R 1/06772; G01R 1/071; H04B 10/11; H04B 2210/006

(57) ABSTRACT

A probe includes a main electro-optical modulator (130), first (150) and second (160) optical couplers each having a respective input (152, 162), through (154, 164) and isolated (156, 166) port, and reference (170) and test (174) optical detectors. Reference light and test light, respectively, are received at the inputs (152, 162) of the optical couplers (150, 160). Main electro-optical modulator 130 includes an RF through-line (136) between input (132) and output (134) RF connectors, and a modulator optical path (138) alongside the RF through-line. The first and second optical couplers couple the reference and test light to opposite ends of the modulator optical path. The reference and test optical detectors are coupled to the second and first isolated ports (166, 156), respectively, to generate reference and test IF signals respectively representing forward and reverse RF signal propagation along the RF through-line. The received reference and test light is modulated at an LO frequency, or an auxiliary electro-optical modulator (180) is provided to modulate unmodulated received light.

### BACKGROUND

Wideband network analysis, ranging from low RF frequencies to hundreds of GHz, continues to present difficult technological challenges to manufacturers of test equipment that operates in wideband frequency ranges of interest that extend to microwave (3-30 GHz) and [symbol] millimeter-wave (30-300 GHz) frequencies. Both the passive and active RF components used in high-performance microwave and millimeter-wave network analyzers represent the state of the art, yet the delivered solutions remain inadequate in many respects. For example, a typical example of a millimeter-wave network analyzer may include a millimeter-wave probe that features precision-machined passive directional couplers fabricated using state-of-the-art wire electrical discharge machining (EDM), multiple high-bandwidth double-balanced mixer circuits, and chains of frequency multipliers and amplifiers. However, the performance offered by these components individually may not be realized when the components are assembled to form the probe due to the lack of a wideband balun capable of properly driving the double-balanced mixer. Another problem in a millimeter-wave probe is high power dissipation due to the large number of wideband linear amplifiers needed. Power dissipation of 10 W per probe is not uncommon.

Replacing some of the electronic components of a millimeter-wave probe with optical components in a conventional topology provides solutions to some of the issues described above. For example, replacing chains of electrical multipliers and amplifiers with high-bandwidth photodiodes (PD's) having reasonable responsivity and, hence, power efficiency reduces the power dissipation of the probe. However, suitable photodiodes are not readily available at reasonable cost. Even if the prices of suitable photodiodes fall significantly, substantial electrical design challenges remain. Wideband directional couplers are very expensive to machine, and multiple directional couplers connected back-to-back are needed to obtain adequate isolation. These issues are severe throughout the millimeter-wave frequency range, with the severity increasing with increasing frequency.

Another potential benefit of using optical components is the ability to replace an electrical balun with an ultra-wideband optical balun. Wideband electrical baluns operating at frequencies greater than about 50 GHz are not readily available.

With electronic components replaced by optical components in a conventional topology, another wideband active circuit is needed, namely, a downconverting mixer. A typical probe has two downconverting mixers, one for reference and one for test. While the design of a wideband double-balanced ring mixer circuit may appear relatively trivial (only four nominally-identical diodes are needed), parasitic resistances, capacitances, and inductances make the design challenging throughout the millimeter-wave frequency range, with the challenge increasing with increasing frequency. In addition, the electrical properties of the packaging become more of an issue with increasing frequency: specifically, the design of the signal and ground launches between the chip and the ceramic carrier becomes more critical. Multi-mode excitation, i.e., the undesired generation of electromagnetic modes other than the intended transmission line mode, becomes more likely with increasing frequency. To address this issue, both the chip and the ceramic carrier must be thinned to the point of mechanical fragility.

Another issue to which wideband network analysis is subject is colloquially known as “mixer bounce.” Mixer bounce occurs when mixer image products generated by the mixer of one probe and coupled through the device under test (DUT) into the mixer of another probe inadvertently resample the DUT. This causes DUTs having a large variation of insertion gain/loss with frequency to exhibit undesirable ghost-like partial transmission artifacts. In traditional, canonical network analyzers, amplifiers are interposed between the directional coupler (coupled and isolated) ports and the mixers to improve isolation and reduce mixer bounce. However, amplifiers for the millimeter-wave frequency range are expensive, have high power dissipation, and may not necessarily provide sufficient isolation.

Accordingly, what is needed is a dual-directional electro-optical probe topology capable of operating in frequency ranges of interest that extend to microwave and millimeter-wave frequencies and that does not suffer from the performance shortcomings, high cost and high power dissipation of a conventional probe based on electronic components or on a mixture of electronic and optical components.

### BRIEF DESCRIPTION OF THE DRAWINGS

FIGS. 1 and 2 are schematic drawings showing respective examples of a dual-directional electro-optic probe (DDEOP) as disclosed herein.

FIGS. 3A and 3B are block diagrams showing examples of the DDEOP shown in FIG. 1 with an internal laser light source and receiving light from an external laser light source, respectively.

FIGS. 4A and 4B are block diagrams showing examples of the DDEOP shown in FIG. 2 with an internal laser light source and receiving light from an external laser light source, respectively.

FIG. 5 is a schematic drawing showing an example of a laser light source that generates modulated reference light and modulated test light in response to a local oscillator signal.

FIG. 6 is a schematic drawing showing an example of a laser light source that generates unmodulated reference light and unmodulated test light.

FIGS. 7 and 8 are block diagrams showing examples of a one-port network analysis system and a multi-port network analysis system, respectively, as disclosed herein.

FIG. 9 is a graph showing a calculated example of effective directivity versus RF frequency of an example of the main electro-optical modulator of the above-described DDEOPs.

FIG. 10 is a graph showing the frequency dependence of the normalized effective coupling between the RF through-line and the modulator optical path of an example of the main electro-optical modulator of the above-described DDEOPs.

FIGS. 11 and 12 are schematic drawings showing examples of a main electro-optical modulator that provides greater directivity at low frequencies.

FIGS. 13 and 14 are schematic drawings showing respective examples of a dual-laser laser light source that generates modulated reference light and modulated test light at different wavelengths.

FIG. 15 is a schematic drawing showing an example of a laser light source that generates unmodulated reference light and unmodulated test light at different wavelengths.

FIG. 16 is a graph showing the seven relevant optical tones that contribute to the reference IF signal generated by the reference optical detector of the above-described DDEOPs in response to reference light phase-modulated by an LO signal and an RF signal.

FIG. 17 is a schematic drawing showing an example of an all-pass filter suitable for converting phase modulation to amplitude modulation.

### DETAILED DESCRIPTION

Embodiments of a dual-directional electro-optic probe (DDEOP, pronounced “dee-dee op”) are disclosed herein. Here, the term “dual-directional” refers to the two propagation directions inherent to the distributed electrical-optical coupling structure of the probe. The probe includes two optical detectors, one for each of the propagation directions.

The dual-directional electro-optic probe (DDEOP) embodiments disclosed herein are based on a longitudinal, directional electro-optical modulator having an RF through-line located alongside a modulator optical path. An RF signal from a host network analyzer propagates in a forward direction along the RF through-line to a device under test (DUT) as a forward RF signal. A portion of the forward RF signal is reflected by the DUT and propagates in a reverse direction along the RF through-line as a reverse RF signal. Reference light propagates in the forward direction along the modulator optical path and is modulated by the forward RF signal. Test light propagates in the reverse direction along the modulator optical path and is modulated by the reverse RF signal. The host network analyzer additionally generates a local oscillator signal offset in frequency from the RF signal by an intermediate frequency. The reference light and test light are additionally modulated by the local oscillator signal. After propagating along the modulator optical path, the reference light and test light are coupled into a reference optical detector and a test optical detector, respectively. In the reference optical detector, sidebands generated by the forward RF signal and sidebands generated by the local oscillator signal beat to generate a reference IF signal that represents the forward RF signal. In the test optical detector, sidebands generated by the reverse RF signal and sidebands generated by the local oscillator signal beat to generate a test IF signal that represents the reverse RF signal. Properties of the DUT at the frequency of the RF signal can be determined from the reference IF signal and the test IF signal.

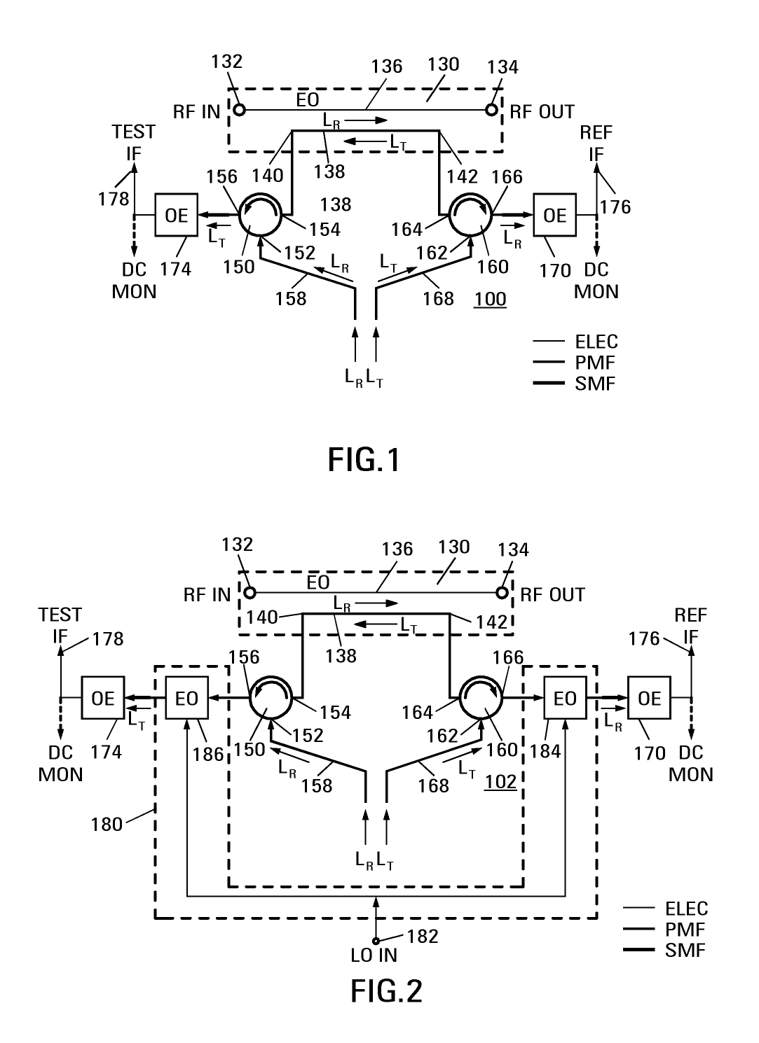

FIG. 1 is a schematic drawing showing an example 100 of a dual-directional electro-optic probe (DDEOP) as disclosed herein. FIG. 2 is a schematic drawing showing another example 102 of a dual-directional electro-optic probe (DDEOP) as disclosed herein. Elements of DDEOP 102 that correspond to elements of DDEOP 100 are indicated using the same reference numerals and will not be separately described. In the following description, the terms reference and test are used simply to distinguish elements of a DDEOP from one another using terminology commonly used in network analysis. The use of these terms does not limit the function of the elements so named: for example, the elements named reference can be used to generate a signal for input to the test input of a network analyzer, and vice versa.

DDEOPs 100 and 102 each include a main electro-optical modulator 130, a first optical coupler 150, a second optical coupler 160, a reference optical detector 170, and a test optical detector 174.

Main electro-optical modulator 130 includes an input RF connector 132, an output RF connector 134, an RF through-line 136 connected between input RF connector 132 and output RF connector 134, and a modulator optical path 138. Modulator optical path 138 extends alongside RF through-line 136 between a first end 140 and a second end 142.

First optical coupler 150 includes a first input port 152, a first through port 154, and a first isolated port 156. First input port 152 is optically coupled to receive reference light LR. First through port 154 is optically coupled to the first end 140 of the modulator optical path 138 of main electro-optical modulator 130. Second optical coupler 160 includes a second input port 162, a second through port 164, and a second isolated port 166. Second input port 162 is optically coupled to receive test light LT. Second through port 164 is optically coupled to the second end 142 of modulator optical path 138.

In the example shown, an optical fiber 158, conveys reference light L_{R} to the first input port 152, and an optical fiber 168 conveys test light L_{T} to second input port 162. Other ways of conveying light to input ports 152, 162 are known and may be used. In an example, the reference light and test light is conveyed to input ports 152, 162, respectively, from respective outputs of a beam splitter (not shown) that constitutes part of DDEOP 100, 102.

Reference optical detector 170 is optically coupled to second isolated port 166 to generate a reference intermediate-frequency (IF) electrical signal representing forward RF signal propagation along the RF through-line 136 of main electro-optical modulator 130. In the example shown, reference optical detector 170 outputs the reference IF signal at a reference IF output 176. Test optical detector 174 is optically coupled to first isolated port 156 to generate a test intermediate-frequency electrical signal representing reverse RF signal propagation along RF through-line 136. In the example shown, test optical detector 174 outputs the test IF signal at a test IF output 178. Forward RF signal propagation is propagation from input RF connector 132 to output RF connector 134. Reverse RF signal propagation is propagation from output RF connector 134 to input RF connector 132.

In DDEOP 100, reference light L_{R} and test light L_{T} received at input port 152 and input port 162, respectively, are modulated at a local oscillator frequency. In DDEOP 102, the reference light and test light received at input port 152 and input port 162, respectively, are unmodulated, and DDEOP 102 additionally includes an auxiliary electro-optical modulator 180 to modulate the reference light and the test light in response to a local oscillator signal.

In the example of DDEOP 102 shown, auxiliary electro-optical modulator 180 includes a reference modulator element 184 and a test modulator element 186. In the example shown, reference modulator element 184 is located between second optical coupler 160 and reference optical detector 170, and test modulator element 186 is located between first optical coupler 150 and test optical detector 174. Modulator elements 184, 186 are connected to receive a common local oscillator signal. In the example shown, modulator elements 184, 186 receive the local oscillator signal from LO input 182. Modulator elements 184, 186 modulate reference light L_{R} and test light LT, respectively, after the reference light and the test light has been modulated by main electro-optical modulator 130 and prior to detection of the reference light by reference optical detector 170 and detection of the test light by test optical detector 174. Modulation of light by auxiliary electro-optical modulator 180 after modulation by main electro-optical modulator 130 will be referred to herein as post modulation. In other implementations of DDEOP 102, modulator elements 184, 186 constituting auxiliary electro-optical modulator 180 are respectively interposed between the source of reference light L_{R} and the first input port 152 of first optical coupler 150, and between the source of test light L_{T} and the second input port 162 of second optical coupler 160. In this example, auxiliary electro-optical modulator 180 modulates the reference light and test light prior to modulation of the reference light and test light by main electro-optical modulator 130. Modulation of light by auxiliary electro-optical modulator 180 prior to modulation by main electro-optical modulator 130 will be referred to herein as pre-modulation.

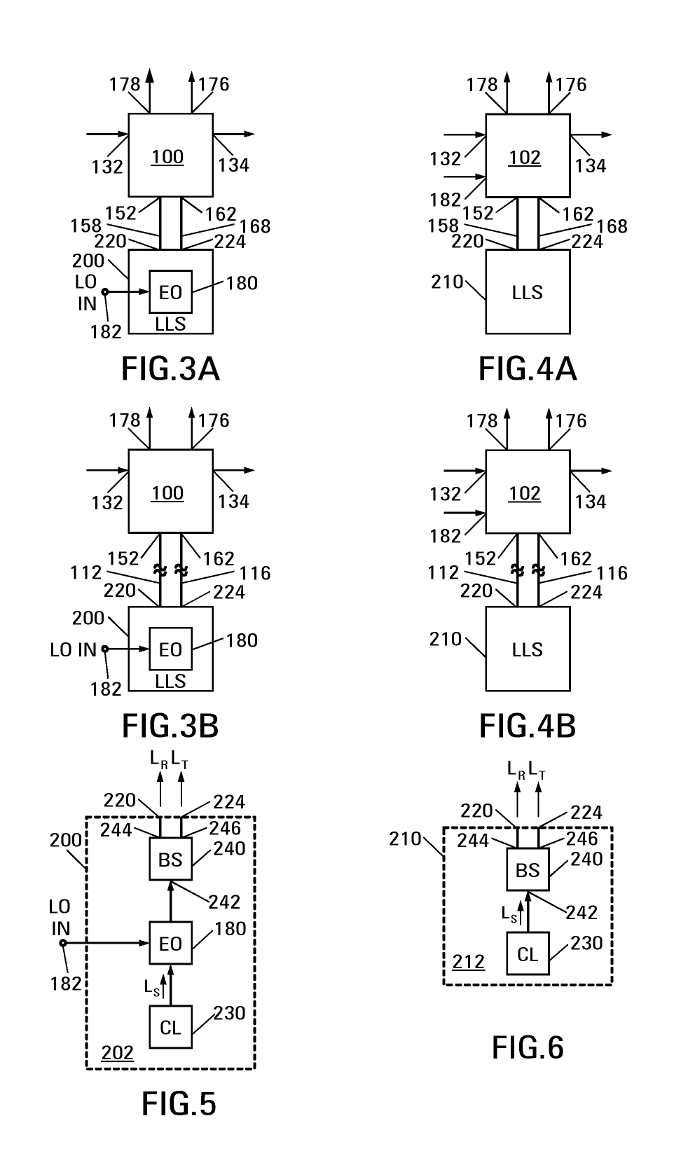

FIG. 3A is a block diagram showing an implementation of DDEOP 100 that additionally includes an internal laser light source 200. A laser light source that is internal to a DDEOP shares a common housing (not shown) as the main electro-optical modulator 130 of the DDEOP. Laser light source 200 generates modulated reference light L_{R} and modulated test light L_{T} for input at the input ports 152, 162 of optical couplers 150, 160, respectively. In the example shown, laser light source 200 includes a reference light output 220 to which the first input port 152 is connected, and a test light output 224 to which second input port 162 is connected. In the example shown, an end of optical fiber 158 remote from first input port 152 is connected to reference light output 220, and an end of optical fiber 168 remote from second input port 162 is connected to test light output 224. As will be described in greater detail below, laser light source 200 additionally includes auxiliary electro-optical modulator 180 that pre-modulates the reference light and test light generated by laser light source 200 in response to a local oscillator signal received at LO input 182.

FIG. 4A is a block diagram showing an implementation of DDEOP 102 that additionally includes an internal laser light source 210. Laser light source 210 generates unmodulated reference light L_{R} and unmodulated test light L_{T} for input at the input ports 152, 162 of optical couplers 150, 160, respectively. In the example shown, laser light source 210 includes a reference light output 220 to which first input port 152 is connected, and a test light output 224 to which second input port 162 is connected. In the example shown, an end of optical fiber 158 remote from first input port 152 is connected to reference light output 220, and an end of optical fiber 168 remote from second input port 162 is connected to test light output 224.

In other examples, internal laser light source 200 and internal laser light source 210 include at least one additional reference light output (not shown) in addition to reference light output 220, and at least one additional test light output (not shown) in addition to test light output 224. The additional reference light outputs and test light outputs allow internal laser light source 200, 210 within an instance of DDEOP 100, 102 additionally to act as an external laser light source for one or more additional instances of DDEOP 100, 102 that lack an internal laser light source.

FIG. 3B is a block diagram showing an implementation of DDEOP 100 that receives reference light L_{R} and test light L_{T} from an external laser light source 200. In this implementation, an optical fiber 112 connects the reference light output 220 of laser light source 200 to the first input port 152 of DDEOP 100, and an optical fiber 116 connects the test light output 224 of laser light source 200 to the second input port 162 of DDEOP 100. FIG. 4B is a block diagram showing an implementation of DDEOP 102 in which laser light source 210 is external to the DDEOP, and respective optical fibers 112, 116 connect the reference light output 220 and the test light output 224 of laser light source 210 to the first input port 152 and the second input port 162, of DDEOP 102. In an example of FIGS. 3B, 4B, the ends of optical fibers 112, 116 remote from light outputs 220, 224 are connected to first input port 152 and second input port 162, respectively. In another example, the ends of optical fibers 112, 116 remote from light outputs 220, 224 are connected to the ends of optical fibers 158, 168 (FIG. 2) remote from first input port 152 and second input port 162, respectively.

In other examples, external laser light source 200 and external laser light source 210 include multiple instances of reference light output 220, and multiple instances of test light output 224. The multiple reference light outputs and test light outputs allow external laser light sources 200, 210 to act as external laser light sources for a corresponding number of instances of DDEOPs 100, 102 that lack an internal laser light source. A single laser light source generating light for multiple DDEOPs will be described in more detail below with reference to FIG. 8.

FIG. 5 is a schematic drawing showing an example 202 of laser light source 200 suitable for use as an internal or external laser light source for DDEOP 100. FIG. 6 is a schematic drawing showing an example 212 of laser light source 210 suitable for use as an internal or external laser light source for DDEOP 102. Reference light L_{R} and test light L_{T} output by laser light sources 202, 212 have the same wavelength. Each of laser light sources 202, 212 includes a common laser 230 and a beam splitter 240. Common laser 230 generates light that is output at both reference light output 220 and at test light output 224 and that will be referred to as system light LS. In the example shown, beam splitter 240 is a two-way beam splitter and has an input 242, a first output 244 optically coupled to reference light output 220, and a second output 246 optically coupled to test light output 224. Input 242 is optically coupled to common laser 230. Beam splitter 240 divides the system light L_{S} output by common laser 230 between first output 244 and second output 246 and, hence, between reference light output 220 and test light output 224.

Referring to FIG. 5, laser light source 202 additionally includes auxiliary electro-optical modulator 180 interposed between common laser 230 and beam splitter 240 to pre-modulate the reference light L_{R} and the test light L_{T} output by laser light source 202 at reference light output 220 and test light output 224, respectively, in response to a local oscillator signal received at LO input 182.

In laser light sources 202, 212, common laser 230 is a continuous-wave laser, such as a distributed feedback (DFB) laser. The wavelength of system light L_{S} generated by common laser 230 is not critical. However, since a large variety of optical components is available for use in optical communication systems, the wavelength of the system light generated by a typical embodiment of common laser 230 is 1.55 μm.

Beam splitter 240 splits system light L_{S} generated by common laser 230 between reference light output 220 and test light output 224. In an example, beam splitter 240 splits system light L_{S} equally between the reference light output and the test light output. In another example, beam splitter 240 splits system light L_{S} unequally between the reference light output and the test light output. Optical elements capable of splitting incident light equally or unequally between two or more output paths are known and may be used. For maximum dynamic range and signal-to-noise ratio, it is advantageous to send more of the system light power to test light output 224. DDEOPs 100, 102 may additionally include an optical amplifier (not shown) ahead of second input port 162 to increase the power of the test light. Additionally or alternatively, laser light sources 200, 210 may additionally include an optical amplifier (not shown) located between the second output 246 of beam splitter 240 and test light output 224 to increase the power of the test light.

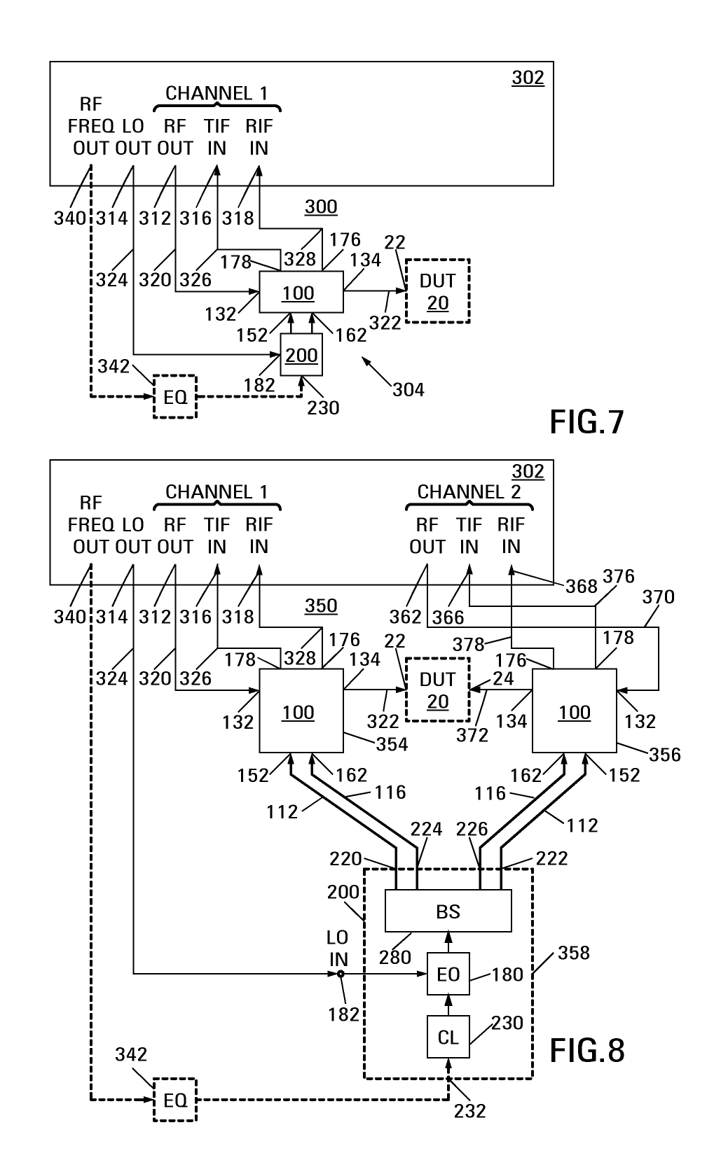

FIG. 7 is a block diagram showing an example of a one-port network analysis system 300 as disclosed herein for performing one-port network analysis using a single instance of the above-described dual-directional electro-optic probes (DDEOPs) 100, 102. Network analysis system 300 includes a network analyzer 302 and a DDEOP 304. In the example shown, DDEOP 304 is implemented using DDEOP 100 described above with reference to FIG. 3A having an internal laser light source 200 that generates modulated reference light L_{R} and modulated test light L_{T} for input to the first input port 152 and the second input port 162, respectively, of DDEOP 100. With the differences noted below, the following description is equally applicable to examples of network analysis system 300 in which DDEOP 304 is implemented using DDEOP 100 with an external laser light source 200 (FIG. 3B), or DDEOP 102 with an internal or external laser light source 210 (FIGS. 4A, 4B). The inputs and outputs of DDEOP 304 are indicated using the same reference numerals as the corresponding inputs and outputs of DDEOPs 100, 102 described above with reference to FIGS. 1 and 2. In an example, network analyzer 302 is a commercially-available network analyzer, such as one of the N5240 series network analyzers sold by Agilent Technologies, Inc., Santa Clara, Calif. Typically, network analyzer 302 is a multi-channel instrument, but only the channel used to perform the one-port measurement is shown in FIG. 7.

Network analyzer 302 includes an RF source having an RF output 312, a local oscillator having an LO output 314, a test IF receiver having a test IF input 316, and a reference IF receiver having a reference IF input 318. Since RF sources, local oscillators and IF receivers are common components of network analyzers, the RF source, local oscillator and IF receivers of network analyzer 302 are not shown in FIG. 7. Each of the RF source and local oscillator of a typical embodiment of network analyzer 302 typically includes a digitally-controlled frequency synthesizer that generates an RF signal that can be swept in frequency over a frequency range of interest. In some applications, the frequency range of interest extends to the hundreds of gigahertz: in other applications, the frequency range of interest extends to frequencies much lower than this. The local oscillator generates an LO signal that is offset in frequency from the RF signal output by the RF source by the specified intermediate frequency of the IF receivers of the network analyzer. The intermediate frequency typically ranges from about 1 MHz to 10 MHz, and is rarely greater than 100 MHz. In another example, the local oscillator generates the LO signal at a frequency having a harmonic that is offset in frequency from the RF signal output by the RF source by the specified intermediate frequency.

An RF connection 320 connects the RF output 312 of network analyzer 302 to the input RF connector 132 of DDEOP 304, and an RF connection 322 connects the output RF connector 134 of the DDEOP to the single port 22 of a device under test (DUT) 20. Thus, the port 22 of DUT 20 is connected to the RF output 312 of network analyzer 302 via the RF through-line 136 of the main electro-optical modulator 130 of DDEOP 304. In the example shown, an RF connection 324 connects the LO output 314 of network analyzer 302 to the LO input 182 of the auxiliary electro-optical modulator 180 (FIG. 5) located within internal laser light source 200. In another example in which laser light source 200 is external to DDEOP 100, RF connection 324 connects the LO output 314 of network analyzer 302 to the LO input 182 of the auxiliary electro-optical modulator 180 located within the external laser light source. In another example in which DDEOP 304 is implemented using DDEOP 102, RF connection 324 connects the LO output 314 of network analyzer 302 to the LO input 182 of the auxiliary electro-optical modulator 180 within DDEOP 102. An RF connection 326 connects the test IF output 178 of DDEOP 304 to the test IF input 316 of the network analyzer. An RF connection 328 connects the reference IF output 176 of DDEOP 304 to the reference IF input 318 of the network analyzer.

Referring additionally to FIGS. 1 and 2, operation of the various implementations 100, 102 of DDEOP 304 in network analysis system 300 will now be described. Reference light L_{R} and test light L_{T} generated by laser light source 200 is received at the first input port 152 of first optical coupler 150 and at the second input port 162 of second optical coupler 160, respectively. In examples in which reference light L_{R} and test light L_{T} are generated by laser light sources 202, 212 described above with reference to FIGS. 5 and 6, reference light L_{R} and test light L_{T} have the same wavelength, since they are both generated by common laser 230. Examples of laser light sources 200, 210 that generate reference light L_{R} and test light L_{T} at different wavelengths will be described below. In the example shown, in which reference light L_{R} and test light L_{T} are generated by laser light source 200, the reference light and test light are pre-modulated by the auxiliary electro-optical modulator in the laser light source in response to the local oscillator signal received from the LO output of network analyzer 302. In an example in which reference light L_{R} and test light L_{T} are generated by laser light source 210, the reference light and test light are unmodulated.

First optical coupler 150 couples the reference light L_{R} received at first input port 152 via first through port 154 to the first end 140 of the modulator optical path 138 of main electro-optical modulator 130. As it propagates along modulator optical path 138, the reference light is modulated by the RF signal received from network analyzer 302 propagating in the forward direction along RF through-line 136 from input RF connector 132 to output RF connector 134. Modulation of the reference light by the RF signal propagating in the forward direction generates optical sidebands in the reference light. These optical sidebands will be referred to herein as RF sidebands in view of their relationship to the RF signal. The RF sidebands are shifted in frequency relative to reference light L_{R} by the frequency of the RF signal.

Reference light L_{R} exits modulator optical path 138 at the second end 142 thereof and enters second optical coupler 160 via second through port 164. The second optical coupler couples the reference light received at second through port 164 to reference optical detector 170 via second isolated port 166. At reference optical detector 170, the reference light not only includes the RF sidebands generated by the forward-propagating RF signal in main electro-optical modulator 130, but also includes additional optical sidebands generated by auxiliary electro-optical modulator 180 modulating the reference light in response to the LO signal received from the LO output 314 of network analyzer 302. The additional optical sidebands will be referred to herein as LO sidebands due to their relationship to the LO signal. In DDEOP 100, the LO sidebands are generated by auxiliary electro-optical modulator 180 within laser light source 200 and constitute part of the modulated reference light received by DDEOP 100. In DDEOP 102, the LO sidebands are generated by reference modulator element 184 modulating the reference light. In DDEOPs 100, 102, the LO sidebands are shifted in frequency relative to reference light L_{R} by the frequency of the LO signal received by the auxiliary electro-optical modulator, or by a harmonic of the LO signal.

In DDEOPs 100, 102, reference optical detector 170 detects the modulated reference light incident thereon to generate the reference IF signal, which is an electrical signal. In the process of detecting the modulated reference light, the RF sidebands in the modulated reference light beat with the LO sidebands in the modulated reference light to generate the reference IF signal at a frequency equal to the frequency difference between the RF sidebands and the LO sidebands, i.e., equal to the frequency difference between the RF signal and the LO signal. Reference optical detector 170 outputs the reference IF signal at reference IF output 176.

Second optical coupler 160 couples test light L_{T} received at second input port 162 via second through port 164 to the second end 142 of the modulator optical path 138 of main electro-optical modulator 130. As it propagates along modulator optical path 138, the test light is modulated by the RF signal propagating in the reverse direction along RF through-line 136 from output RF connector 134 to input RF connector 132. The RF signal propagating in the reverse direction is a portion of the RF signal propagating in the forward direction that has been reflected by DUT 20. Modulation of the test light by the RF signal propagating in the reverse direction generates RF sidebands (which are actually optical sidebands, as noted above) in the test light. The RF sidebands are shifted in frequency relative to the test light by the frequency of the RF signal.

Test light L_{T} exits modulator optical path 138 at the first end 140 thereof, and enters first optical coupler 150. The first optical coupler couples the test light received at first through port 154 to test optical detector 174 via first isolated port 156. At test optical detector 174, the test light not only includes the RF sidebands generated by the reverse-propagating RF signal in main electro-optical modulator 130, but also includes LO sidebands (which are actually optical sidebands) generated by auxiliary electro-optical modulator 180 modulating the test light in response to the LO signal received from the LO output 314 of network analyzer 302. In DDEOP 100, the LO sidebands are generated by auxiliary electro-optical modulator 180 within laser light source 200 and constitute part of the modulated test light input to DDEOP 100. In DDEOP 102, the LO sidebands are generated by test modulator element 186 modulating the test light. In DDEOPs 100, 102, the LO sidebands are shifted in frequency relative to the test light by the frequency of the LO signal received by the auxiliary electro-optical modulator, or by a harmonic of the LO signal.

In DDEOPs 100, 102, test optical detector 174 detects the modulated test light incident thereon to generate the test IF signal, which is an electrical signal. In the process of detecting the modulated test light, the RF sidebands in the test light beat with the LO sidebands in the test light to generate the test IF signal at a frequency equal to the frequency difference between the RF sidebands and the LO sidebands, i.e., equal to the frequency difference between the RF signal and the LO signal. Test optical detector 174 outputs the test IF signal at test IF output 178.

Network analyzer 302 receives the reference IF signal and test IF signal output by DDEOP 304 at its reference IF input 318 and its test IF input 316, respectively. Network analyzer 302 subjects the reference IF signal and the test IF signal to complex (real and imaginary part) analog-to-digital conversion, to generate respective digital values that represent the amplitude and phase of the reference IF signal and the test IF signal, respectively. From these digital values, network analyzer 302 can calculate various one-port properties of DUT 20 such as, but not limited to, return loss/gain and reflection phase. Typical examples of network analyzer 302 additionally display the frequency dependence of such calculated properties of DUT 20 on a display (not shown).

FIG. 8 is a block diagram showing an example of a network analysis system 350 as disclosed herein for performing multiple-port network analysis using multiple instances of the above-described DDEOPs 100, 102. In the example shown, the multiple-port network analysis is two-port network analysis for which two DDEOPs are used. Network analysis system 350 includes network analyzer 302, DDEOPs 354, 356, and an external laser light source 358 that is an implementation of laser light source 200. Note the mirrored orientation of DDEOP 356 relative to DDEOP 354.

As noted above, network analyzer 302 is a multichannel network analyzer. To simplify the drawing, only two channels of multichannel network analyzer 302 are shown. In the example shown, DDEOPs 354, 356 are each implemented using a respective instance of DDEOP 100 described above with reference to FIG. 3B in which laser light source 200 is external to the DDEOP. With the differences noted below, the following description is equally applicable to examples of network analysis system 350 in which DDEOPs 354, 356 are each implemented using a respective instance of DDEOP 100 with internal laser light source 200 (FIG. 3A) or a respective instance of DDEOP 102 having internal or external laser light source 210 (FIGS. 4A, 4B). The inputs and outputs of DDEOPs 354, 356 are indicated using the same reference numerals as the corresponding inputs and outputs of DDEOPs 100, 102.

Laser light source 358 is similar in structure to laser light source 202 described above with reference to FIG. 5, except that 2N-way beam splitter 280 is substituted for 2-way beam splitter 240. N is the number of DDEOPs for which laser light source 358 generates light. In the example shown, N=2, and laser light source 358 has reference light outputs 220, 222 and test light outputs 224, 226 each connected to a respective output of 4-way beam splitter 280. Respective optical fibers 112, 116 connect reference light output 220 and test light output 224 to the first input port 152 and the second input port 162 of DDEOP 354. Respective optical fibers 112, 116 connect reference light output 222 and test light output 226 to the first input port 152 and the second input port 162 of DDEOP 356.

Network analyzer 302 includes the above-described RF source, local oscillator and IF receivers. The output of the RF source is switchable between channel 1 RF output 312 and a channel 2 RF output 362. The RF output to which the RF source is not connected is terminated with a termination having the characteristic impedance of network analyzer 302. The local oscillator of network analyzer 302 is connected to LO output 314. Channel 1 test IF input 316 connected to a channel 1 test IF receiver, and channel 1 reference IF input 318 is connected to a channel 1 reference IF receiver. A channel 2 test IF input 366 is connected to a channel 2 test IF receiver, and a channel 2 reference IF input 368 is connected to a channel 2 reference IF receiver. Since RF sources, local oscillators and IF receivers are common components of network analyzers, the RF source, local oscillator and IF receivers within network analyzer 302 are not shown in FIG. 8.

RF connection 320 connects the channel 1 RF output 312 of network analyzer 302 to the input RF connector 132 of DDEOP 354, and RF connection 322 connects the output RF connector 134 of the DDEOP to the first port 22 of device under test (DUT) 20. Thus, the first port of DUT 20 is connected to the channel 1 RF output 312 of network analyzer 302 via the RF through-line 136 of the main electro-optical modulator 130 of DDEOP 354. In the example shown, RF connection 324 connects the LO output 314 of network analyzer 302 to the LO input 182 of auxiliary electro-optical modulator 180 located in external laser light source 358 that generates modulated light for both DDEOPs 354, 356. In another example in which DDEOPs 354, 356 are implemented using DDEOPs 100 with respective internal laser light sources 200 (FIG. 3A), or using DDEOPs 102 with respective internal or external laser light sources 210 (FIGS. 4A, 4B) or with a common external laser light source 210, RF connection 324 connects LO output 314 to the LO inputs 182 of the DDEOPs. RF connection 326 connects the test IF output 178 of DDEOP 354 to the channel 1 test IF input 316 of the network analyzer. RF connection 328 connects the reference IF output 176 of the DDEOP 354 to the channel 1 reference IF input 318 of the network analyzer.

An RF connection 370 connects the channel 2 RF output 362 of network analyzer 302 to the input RF connector 132 of DDEOP 356, and an RF connection 372 connects the output RF connector 134 of DDEOP 356 to a second port 24 of DUT 20. Thus, the second port 24 of DUT 20 is connected to the channel 2 RF output 362 of network analyzer 302 via the RF through-line 136 of the main electro-optical modulator 130 of DDEOP 356. An RF connection 376 connects the test IF output 178 of DDEOP 356 to the channel 2 test IF input 366 of the network analyzer. An RF connection 378 connects the reference IF output 176 of DDEOP 356 to the channel 2 reference IF input 368 of the network analyzer.

Operation of DDEOPs 354, 356 in network analysis system 350 is similar to the operation of DDEOP 304 in network analysis system 300, and will not be separately described. Network analyzer 302 receives the reference IF signal and test IF signal output by DDEOP 354 at its channel 1 reference IF input 318 and its channel 1 test IF input 316, respectively. Network analyzer 302 subjects the channel 1 reference IF signal and the test IF signal received from DDEOP 354 to complex (real and imaginary part) analog-to-digital conversion, to generate respective digital values that represent the amplitude and phase of the channel 1 reference IF signal and the test IF signal, respectively. Network analyzer 302 additionally receives the reference IF signal and test IF signal output by DDEOP 356 at its channel 2 reference IF input 368 and its channel 1 test IF input 366, respectively. Network analyzer 302 subjects the channel 2 reference IF signal and the test IF signal received from DDEOP 356 to complex (real and imaginary part) analog-to-digital conversion, to generate respective digital values that represent the amplitude and phase of the channel 2 reference IF signal and the test IF signal, respectively. From these digital values, network analyzer 302 can calculate various properties of the DUT 20 such as, but not limited to, return loss/gain, insertion loss/gain, reflection phase, and transmission phase. Typical examples of network analyzer 302 additionally display the frequency dependence of such calculated properties of DUT 20 on a display (not shown).

In an example in which network analysis system 350 determines S-parameters of DUT 20, network analyzer 302 outputs the RF signal from the channel 1 RF output 312 to the first port 22 of DUT 20. The channel 2 RF output 362 of the network analyzer is terminated. Network analyzer 302 calculates the S11 of DUT 20 by dividing the digital value that represents the channel 1 test IF signal by the digital value that represents the channel 1 reference IF signal, and calculates the S21 of DUT 20 by dividing the digital value that represents the channel 2 test IF signal by the digital value that represents the channel 1 reference IF signal. Network analyzer 302 next outputs the RF signal from the channel 2 RF output 362 to the second port 24 of DUT 20. The channel 1 RF output 312 is terminated. Network analyzer 302 calculates the S22 of DUT 20 by dividing the digital value that represents the channel 2 test IF signal by the digital value that represents the channel 2 reference IF signal, and calculates the S12 of DUT 20 by dividing the digital value that represents the channel 1 test IF signal by the digital value that represents the channel 2 reference IF signal.

Dual-directional electro-optic probes (DDEOPs) 100, 102 will now be described in more detail with reference to FIGS. 1-6. In main electro-optical modulator 130, modulator optical path 138 is electro-optically coupled in a distributed traveling-wave sense to RF through-line 136 that extends between input RF connector 132 and output RF connector 134. The longitudinal geometry of main electro-optical modulator 130 is distinct from the geometry of conventional high-speed electro-optic probes, in which the optical signal propagates in a direction orthogonal to that of the RF signal. The conventional arrangement results in a tiny interaction zone between the RF signal and the optical signal. Typical dimensions of the interaction zone range from a few micrometers to about 200 μm, depending on the maximum operating frequency of the probe. The tiny interaction zone obviates the need for velocity matching, but is also the main cause of conventional electro-optical probes having inadequate sensitivity for many applications. Moreover, transverse electro-optical probes are more invasive than is generally supposed, because the use of high dielectric constant materials, such as lithium tantalate (LiTaO3) or zinc telluride (ZnTe), common materials in such probes, lowers the local impedance and velocity of the electrical transmission line being probed. Finally, the conventional transversely-oriented electro-optical probe geometry is inherently non-directional.

To obtain the sensitivity advantages of a co-propagating geometry, RF through-line 136 and modulator optical path 138 of main electro-optical modulator 130 are velocity matched such that RF signals propagating along the RF through-line and light propagating in the same direction along the modulator optical path have propagation velocities that are matched within a defined percentage. In an example, the percentage is 3%, in a better example, the percentage is 1%, and in a 2014 state-of-the-art example, the percentage is 0.5%. Velocity-matched components are commercially available from many manufacturers and may be used as part of main electro-optical modulator 130. Velocity matching provides an interaction length measured in centimeters rather than less than a few hundred micrometers. Better velocity matching increases the interaction length. The increased interaction length provides a significant increase in sensitivity. Conversely, sensitivity is reduced when the RF and optical signals counter-propagate due to the large velocity mismatch between the signals. Velocity, as distinguished from speed, is a vector and hence its direction matters. Consequently, DDEOPs 100, 102 have significant directional properties. Direction-dependent sensitivity is characterized as directivity. High directivity is one of the beneficial features of DDEOPs 100, 102.

In DDEOPs 100, 102, reference light L_{R} propagates from first input port 152 through first optical coupler 150 and first through port 154 to the first end 140 of the modulator optical path 138 of main electro-optical modulator 130, and further propagates through the modulator optical path to second end 142. In modulator optical path 138, reference light L_{R} co-propagates with, and is modulated by, the forward RF signal propagating in the forward direction along RF through-line 136 from input RF connector 132 to output RF connector 134. Additionally, the reference light counter-propagates with, and is minimally modulated, if at all, by the reverse RF signal propagating in the reverse direction along RF through-line 136 from output RF connector 134 to input RF connector 132. Thus, the modulation of the reference light output at the second end 142 of modulator optical path 138 principally represents the forward RF signal propagation along RF through-line 136.

Moreover, test light L_{T} propagates from second input port 162 through second optical coupler 160 and second through port 164 to the second end 142 of modulator optical path 138, and further propagates through the modulator optical path to first end 140. In modulator optical path 138, test light L_{T} co-propagates with, and is modulated by, the reverse electrical signal propagating in the reverse direction along RF through-line 136 from output RF connector 134 towards input RF connector 132. Additionally, the test light counter-propagates with, and is minimally modulated, if at all, by the forward electrical signal propagating in the forward direction along RF through-line 136 from input RF connector 132 to output RF connector 134. Thus, the modulation on the test light output at the first end 140 of modulator optical path 138 principally represents the reverse RF signal propagation along RF through-line 136.

A passive directional coupler can be regarded as having an input port, a through port, a coupled port and an isolated port. Such a directional coupler couples a defined fraction of the power of an input signal received at the input port to the coupled port. The coupled port is coupled to the isolated port by symmetry/reciprocity. The directivity (D) of the directional coupler is defined as the ratio, typically expressed in decibels (dB), of the power of the signal received at the coupled port to the power of the signal received at the isolated port. This assumes:

the input signal is received at the input port,

the through port is terminated with a perfect termination (no reflection), and

identical receivers are connected to the coupled port and the isolated port.

A greater directivity is better than a lesser directivity. For an ultra-broadband directional coupler, a directivity greater than 20 dB throughout the specified bandwidth is considered very good. Typical directional couplers rarely have a directivity that exceeds 15 dB over the specified bandwidth. Low directivity in network analysis makes it more difficult to measure the quality of terminations. Low directivity at what will be referred to herein as very low frequencies, e.g., frequencies below about 1 GHz, is tolerable because calibration using high-quality termination standards is quite reliable at very low frequencies. However, low directivity is unacceptable at high frequencies because there are too many unknown frequency-dependent (lossy, dispersive, etc.) passive structures in the signal path for calibration alone to provide acceptable results.

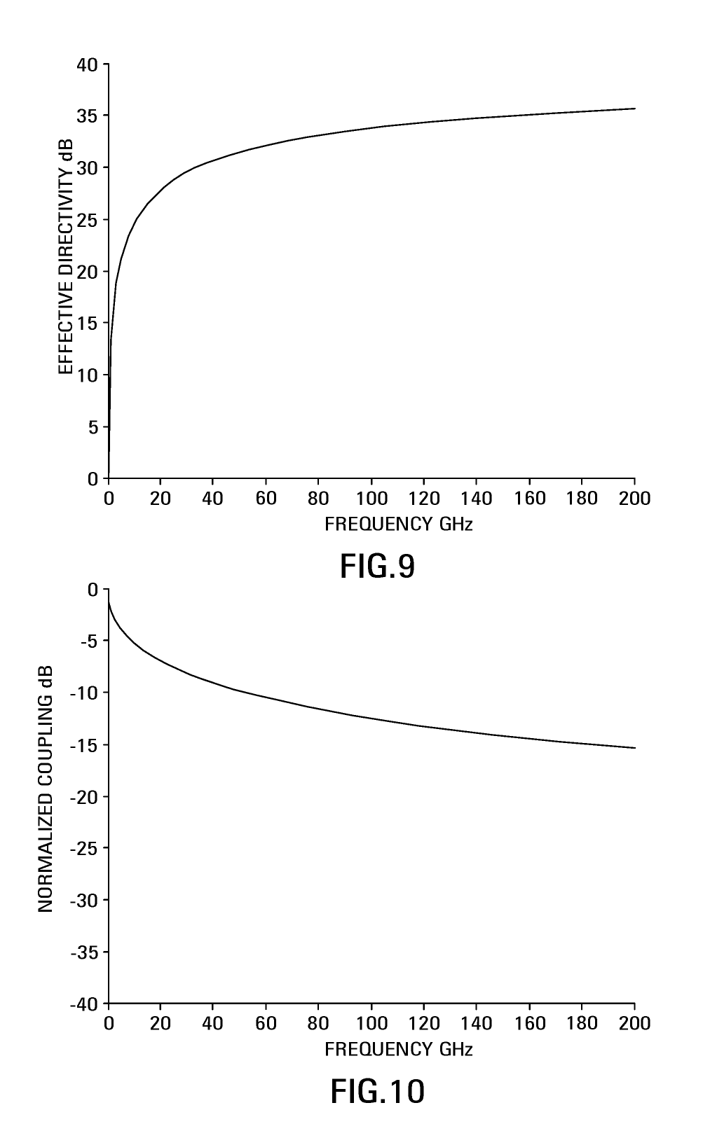

FIG. 9 is a graph showing a calculated example of effective directivity versus RF frequency of an example of main electro-optical modulator 130. The word effective is used in the following sense. In main electro-optical modulator 130, the RF signal propagating along RF through-line 136 imposes the RF sidebands (which, as noted above, are optical sidebands) upon reference light L_{R} or test light L_{T} propagating in the same direction along modulator optical path 138. If it is assumed that optical couplers 150, 160 are substantially identical and that optical detectors 170, 174 are substantially identical, after the photomixing process, in which the LO sideband(s) (which, as noted above, are also optical sidebands) beat with the RF sideband(s) in the optical detector, the ratio between the powers of the respective electrical IF signals output by optical detectors 170, 174 is the same as the ratio between the powers of the forward and reverse RF signals of which the respective IF signals represent downconverted copies. The IF signals output by optical detectors 170, 174, respectively, are referred to as the reference IF signal and the test IF signal. These terms are the terms applied to corresponding signals in a conventional network analyzer probe. The LO sideband(s) are the optical sidebands imposed on the reference light propagating to reference optical detector 170 and the test light propagating to test optical detector 174, respectively, by auxiliary electro-optical modulator 180, and the RF sideband(s) are the optical sidebands imposed on the reference light and the test light propagating along modulator optical path 138 by the RF signal propagating along the RF through-line 136 of main electro-optical modulator 130. The effective directivity, then, is simply the ratio of the power of the test IF signal output by optical detector 174 to the power of the reference IF signal output by optical detector 170. This assumes:

the RF signal input is input at the input RF connector 132 of RF through-line 136,

the output RF connector 134 of RF through-line 136 is terminated with a perfect termination (no reflection), and

optical couplers 150, 160 are substantially identical and optical detectors 170, 174 are substantially identical (as noted above).

Due to the symmetry of DDEOPs 100, 102, the effective directivity could also be defined with the RF input signal input at output RF connector 134 and input RF connector 132 terminated with a perfect termination. In this case, optical detector 170 is the test optical detector and outputs the test IF signal, and optical detector 174 is the reference optical signal and outputs the reference IF signal.

With regard to the parameters assumed in the above description of FIG. 9, the velocities of the optical and RF signals in main electro-optical modulator 130 are represented simply by the optical group velocity of the optical signal and the electrical phase velocity of the RF signal. In the example shown, the optical group velocity and the electrical phase velocity are mismatched by about 2%, which represents the residual velocity mismatch of an implementation of main electro-optical modulator 130 that is nominally velocity-matched. In the following description, RF through-line 136 is assumed to be composed of a signal line (not shown) and a ground conductor (not shown), and to have an impedance of 50Ω. The insertion loss of RF through-line 136 is assumed to be dominated by skin effect conductor loss. To model the skin effect, an effective net conductor width W_{eff} of RF through-line 136 of 5 μm is assumed. The effective net conductor width W_{eff} is given by:

W_{eff}=W_{s,eff}W_{g,eff}/(W_{s,eff}W_{g,eff}),

where:

W_{s,eff} is the effective net conductor width of the signal line of RF through-line 136, and

W_{g,eff} is the effective width of the ground conductor of the RF through-line.

A smaller value of W_{eff} results in a higher skin effect loss. In an example, the material of RF through-line 136 is copper (Cu) at room temperature, and the length of RF through-line 136 is 50 mm.

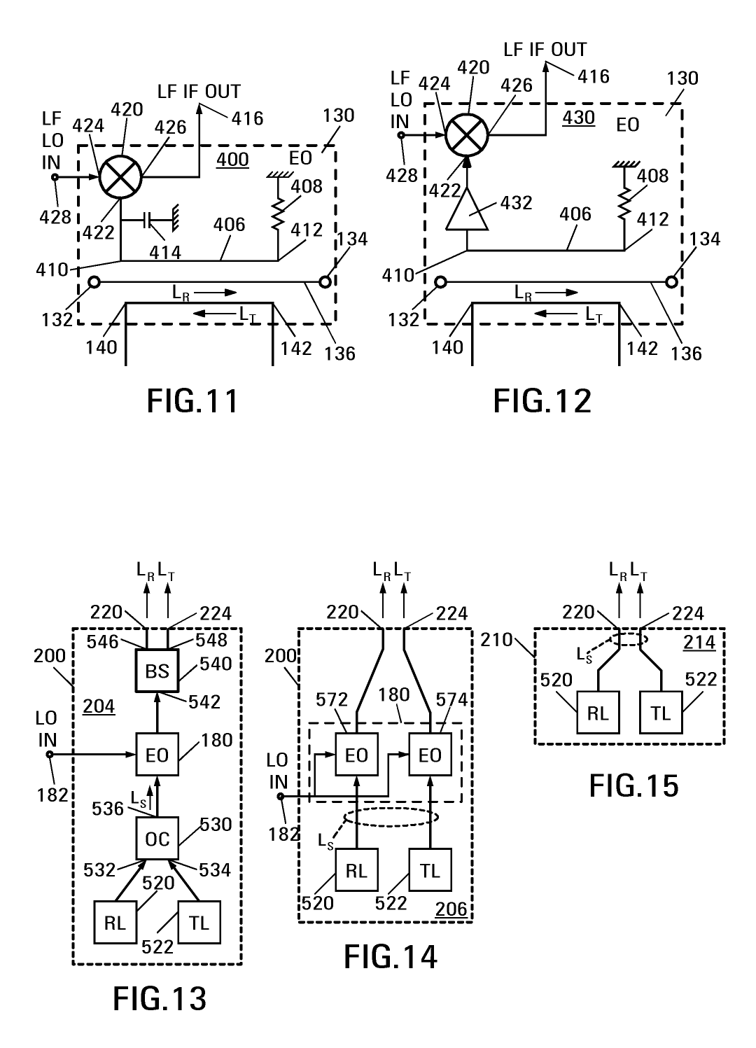

A threshold frequency can be assigned to embodiments of main electro-optical modulator 130 having the directivity characteristic illustrated in FIG. 9. The threshold frequency is the frequency at which the effective directivity falls below a threshold directivity. The threshold directivity depends on the application. In an example, the threshold directivity is 20 dB. In the example shown in FIG. 9, the directivity falls below the 20 dB threshold directivity at frequencies below about 5 GHz. At frequencies above the threshold frequency, the directivity continues to increase with increasing frequency. This is in contrast to conventional all-electrical directional couplers, in which the directivity decreases with increasing frequency. Similar to conventional directional couplers, the directivity of main electro-optical modulator 130 falls to unity (0 dB) at very low frequencies, but, as mentioned above, there are many known workarounds for the lack of directivity at very low frequencies. The reason for the lack of directivity at very low frequencies is that the length of main electro-optical modulator 130 is short compared with the wavelength at these frequencies so that there is no distinction between a forward-traveling and a reverse-traveling electrical wave along the length of RF through-line 136. In other words, the voltage distribution along the length of the RF through-line is substantially uniform at very low frequencies. As frequency rises, the velocity distinction between forward and reverse directions translates to an electro-optical interaction overlap integral distinction, hence the excellent directivity at high frequencies shown in FIG. 9. Frequencies between very low frequencies, at which reliable workarounds for the lack of directivity exist, and the above-described threshold frequency will be referred to herein simply as low frequencies. Embodiments of main electro-optical modulator 130 that overcome poor directivity at low frequencies will be described below with reference to FIGS. 11 and 12.

Referring again to FIGS. 1 and 2, in some embodiments, main electro-optical modulator 130 is implemented using the chip of a commercially-available Mach-Zehnder intensity modulator. In almost all commercially-packaged electro-optical modulators, the manufacturer designates an input fiber (usually polarization maintaining), an output fiber (usually not polarization maintaining), and an RF input connection. Some models have an RF output connection, whereas others have an internal 50Ω load. In main electro-optical modulator 130, the chip in and on which RF through-line 136 and modulator optical path 138 are formed is packaged such that there are no distinctions between inputs and outputs. Instead, main electro-optical modulator 130 has a respective polarization-maintaining (PM) fiber connected at each end 140, 142 of modulator optical path 138, and a respective RF connector 132, 134 at each end of RF through-line 136.

The use of materials having higher electro-optical coefficients and lower dielectric constants is advantageous in main electro-optical modulator 130. Using a material having a higher electro-optical coefficient enables the lengths of RF through-line 136 and modulator optical path 138 needed to provide a specified sensitivity at very low frequencies to be reduced. Reducing the length of RF through-line 136 reduces electrical losses in the RF through-line at very high frequencies. Using a material with a lower dielectric constant reduces dispersion in RF through-line 136, which increases the bandwidth over which velocity matching is obtained. Using a material with a lower dielectric constant also allows RF through-line 136 to have an increased effective net conductor width Weff for a given characteristic impedance. The increased effective net conductor width reduces electrical losses in the RF through-line, which reduces the frequency dependence of the normalized coupling characteristic of main electro-optical modulator 130. The frequency dependence of the normalized coupling characteristic of the main electro-optical modulator will be described next with reference to FIG. 10.

FIG. 10 is a graph showing the frequency dependence of the normalized effective coupling between the RF through-line 136 and the modulator optical path 138 of an example of main electro-optical modulator 130. In this example, the optical group velocity=c/2.25 (where c is the velocity of light in vacuo), the electrical phase velocity=c/2.25, and the effective net conductor width We of RF through-line 136=10 μm. The coupling is normalized to coupling at very low frequencies, i.e., the normalized coupling shown is the ratio between the power of the IF signal at the frequency indicated and the power of the IF signal when the RF frequency is very low, e.g., about 1 GHz. Coupling is somewhat of a misnomer because in principle no electrical power is extracted from RF through-line 136, as would be the case in a conventional electrical directional coupler. Rather, the term coupling is used here to simply designate the power of the respective IF signal(s) representing the forward and reverse RF signals in RF through-line 136. Coupling is strongest at very low frequencies because the attenuation of RF signals by RF through-line 136 is negligible at very low frequencies compared with the attenuation of the RF signals at much higher frequencies. As the frequency of the RF signal increases into the gigahertz range, the narrow effective conductor width of RF through-line 136 in conjunction with its finite conductivity and nonzero length results in significant attenuation of the RF signal due to the skin effect. Consequently, the effective electro-optical interaction length of main electro-optical modulator 130 decreases below the actual physical length over which the electro-optical interaction takes place.

The reduction in effective coupling with increasing frequency can easily be compensated for by applying equalization to laser light sources 200, 210 to increase the power of the system light L_{S} generated by laser light sources 200, 210 as the frequency of the RF signal propagating along RF through-line 136 increases. The example shown in FIG. 10 exhibits an approximately 15 dB reduction in coupling at 200 GHz compared with the coupling at very low frequencies. This reduction in coupling can be compensated for by increasing the power of system light L_{S} by approximately 7.5 dB when the frequency of the RF signal is about 200 GHz. In general, an X dB reduction in coupling can be compensated for by increasing the power of the system light by X/2 dB. The factor of two occurs because an X/2 dB increase in the power of system light L_{S} increases the power of the both the LO sidebands and the RF sidebands in reference light L_{R} and test light L_{T} by X/2 dB. As long as optical detectors 170, 174 do not saturate, the power of the reference IF signal and the test IF signal is proportional to the product of the power of the RF sidebands and the power of the LO sidebands. Consequently, an increase of X/2 dB in the power of system light L_{S} increases the power of the IF signals by X dB.

In embodiments in which the above-described intensity equalization is applied, the examples of network analyzer 302 shown in FIGS. 7 and 8 additionally includes an RF frequency output port 340 at which the network analyzer outputs an analog signal or a digital value that represents the frequency of the RF signal generated by the RF source (not shown) of the network analyzer. Additionally, each laser light source 200, 358 includes an intensity control input 232. An analog control signal or a digital value received at intensity control input controls the intensity of the system light L_{S} generated by common laser 230 (FIGS. 5 and 6) or by reference laser 520 and test laser 522 (FIGS. 13-15, described below). RF frequency output port 340 is linked to intensity control input 232 via an equalizer module 342 that converts the analog signal or digital value representing the frequency of the RF signal to an analog signal or digital value that causes laser light source 200, 358 to generate the system light with an intensity corresponding to the frequency the RF signal. Equalizer module 342 includes a characteristic that is the inverse of FIG. 10 (scaled by a factor of one half) represented by an equation, a lookup table, or in some other suitable manner. In another example, equalizer module 342 constitutes part of laser light source 200.

The fastest electro-optical modulators available in 2013 have about 100 GHz of 3 dB bandwidth, but equalizing the power of the system light as just described can be used to extend the frequency range of such modulators to 200 or even 300 GHz when such an electro-optical modulator is used as main electro-optical modulator 130.

Reference optical detector 170 and test optical detector 174 are each implemented using standard (in the optical communications industry) optical and optoelectronic receiver hardware. The simplest implementation of each optical detector is a low-speed photodiode (PD). A low-speed photodiode can be used to implement the optical detectors because the optical detectors need only respond up to the frequency of the IF signals. In network analysis, typical IF frequencies are in the range 1-10 MHz, and rarely exceed 100 MHz. In some implementations, a higher signal-to-noise ratio (SNR) can be obtained by preceding each photodiode with a respective optical low noise amplifier (O-LNA—not shown). An O-LNA in series with a photodiode will be regarded as constituting an optical detector in this disclosure.

The low frequency of the IF signals that optical detectors 170, 174 are expected to generate enables the photodiodes used as the optical detectors to withstand the increases in the power of system light L_{S} contemplated in the above description of equalization. Since the photodiodes need only respond at the frequency (typically 10 MHz) of the IF signals, photodiodes that are much larger in area than the high-speed photodiodes used for detection at 100 GHz (or even 50 GHz) may be used to implement optical detectors 170, 174. The increased mesa area and volume of such photodiodes translate to a much less tightly focused light beam and to a greatly reduced power density for a given incident light power. The reduction in power dissipation density applies both to optical heating and to DC heating of the photodiode due to the product of the photocurrent and the DC voltage bias applied to the photodiode. In some embodiments, the low frequency of the IF signals allows the photodiodes to be operated unbiased.

Since typical implementations of main electro-optical modulator 130 are polarization sensitive, the optical components of DDEOP 100, 102, and the optical fibers that interconnect the optical components are typically polarization-maintaining. Additionally, in embodiments of DDEOPs 100, 102 in which main electro-optical modulator 130 is polarization sensitive, optical fibers 112, 116 that couple external laser light source 200, 210 (FIGS. 3B, 4B) to the DDEOP are also polarization-maintaining. Alternatively, the optical components of DDEOPs 100, 102 and the optical fibers interconnecting them are implemented using non-polarization-maintaining components, but a reference polarization controller (not shown) is interposed between first optical coupler 150 and the first end 140 of modulator optical path 138, and a test polarization controller (not shown) is interposed between second optical coupler 160 and the second end 142 of the modulator optical path. In embodiments in which main electro-optical modulator 130 is not polarization sensitive, the optical components of DDEOPs 100, 102 and the optical fibers interconnecting them need not be polarization maintaining.

In the examples of DDEOPs 100, 102 shown in FIGS. 1 and 2, first optical coupler 150 and second optical coupler 160 are implemented using respective three-port optical circulators. In another example, respective 2×2 optical couplers (not shown) are used as optical couplers 150, 160. In an example in which first optical coupler 150 is implemented using a 2×2 optical coupler, the 2×2 optical coupler has an input port, a through port, and an isolated port that respectively provide the first input port 152, the first through port 154, and the first isolated port 156 of first optical coupler 150. A 2×2 optical coupler implementation of second optical coupler 160 has corresponding connections. A 2×2 optical coupler additionally has an unused coupled port through which half of the power of the reference light or test light received at the input port of the 2×2 optical coupler is lost, but the power of laser light source 200, 210 can be increased by a factor of four to compensate for this loss. The coupled port of the 2×2 optical coupler can be optically coupled to an optical fiber a meter or more long that is terminated at its distal end to prevent the lost light power from heating the DDEOP.

Auxiliary electro-optical modulator 180 located in laser light source 200 modulates reference light L_{R} and test light L_{T} received by DDEOP 100 regardless of whether laser light source 200 is internal or external to the DDEOP. Auxiliary electro-optical modulator 180 is implemented using an electro-optical amplitude modulator. Auxiliary electro-optical modulator 180 is internal to DDEOP 102, and each modulator element 184, 186 is implemented using a respective electro-optical amplitude modulator. The amplitude modulators are electrically driven by the LO signal received at LO input 182. Modulation by the LO signal generates the LO sidebands at frequencies shifted relative to the frequency of the system light generated by common laser 230 by integer multiples of the frequency of the LO signal.

In some embodiments, auxiliary electro-optical modulator 180 is similar in structure to main electro-optical modulator 130. In other embodiments, auxiliary electro-optical modulator 180 differs in structure from main electro-optical modulator 130, and may even have much lower bandwidth. Auxiliary electro-optical modulator 180 may have a lower bandwidth because it can be driven with more LO signal power than is needed to modulate at the frequency of the LO signal. Increasing LO signal power increases the power of the higher-order LO sidebands at the expense of a reduction of the power of the lower-order LO sidebands. Overdriving the auxiliary electro-optical modulator essentially multiplies the frequency of the local oscillator before the LO sidebands are photomixed with the RF sidebands generated by main electro-optical modulator 130 in optical detectors 170, 174.

Dual-directional electro-optic probes 100, 102 substantially reduce, or even eliminate, the phenomenon of the mixer bounce described above. In an example, such as that shown in FIG. 8, a multi-port network analysis system is constructed using an instance of DDEOP 100 or DDEOP 102 for each port head. Such a network analysis system can be used to characterize DUTs that are challenging to characterize at all frequencies because of their large range of transmittance as a function of frequency. An example of a DUT that is challenging to characterize is a high-quality bandpass filter. In DDEOP 100, 102, since the mixing occurs in optical detectors 170, 174, any “mixer” associated with Port J (e.g., the optical detectors 170, 174 of the DDEOP constituting the port head associated with port J) is opto-isolated from any “mixer” associated with Port K (e.g., the optical detectors 170, 174 of the DDEOP constituting the port head associated with port K). No path exists for mixer image products generated by the optical detectors of the respective DDEOPs to pass through the DUT. The stopband characteristics of the exemplary bandpass filter are faithfully reported by the network analyzer to which the DDEOPs are connected, free of the partial transmission ghost artifacts seen in a conventional network analyzer.

In applications such as that just described, in which multiple instances of DDEOP 100 or DDEOP 102 are used as respective port heads, external laser light sources 200, 210, including the auxiliary electro-optical modulator 180 of external laser light source 200, can be made common to all of the DDEOP, as described above with reference to FIG. 8. In such applications, 2-way beam splitter 240 is replaced by 2N-way beam splitter 280, where N is the number of DDEOPs that receive light from the laser light source, and the power of the system light generated by common laser 230 is increased by a factor of N. In an example, the 2N-way splitter is an equal 2N-way splitter. In another example, the 2N-way splitter outputs equal light power to each of the reference light outputs, and outputs equal light power to each of the test light outputs, but outputs greater light power to the test light outputs than to the reference light outputs.

DDEOPs 100, 102 lack such expensive and/or power-hungry components as ultrahigh speed (ultra-wideband) RF mixers (optical detectors 170, 174 provide mixing), ultra-wideband RF directional couplers or RF couplers (main electro-optical modulator 130 provides a directional coupler), and electrical or optical baluns (since the mixing occurs in the optical detectors). The local oscillator signal simply resides on the reference light and the test light as optical sidebands. DDEOPs 100, 102 are not subject to mixer bounce because of the optical isolation between the mixers of multiple probes. Additionally, DDEOPs 100, 102 have very low power dissipation, typically, less than 50 mW in a DDEOP having an external laser light source 200, 210 since almost all of the components that dissipate significant power, such as the laser light source, can be located remotely from the DDEOP and can be connected to and from the DDEOP by optical fibers. The only component that must reside in the DDEOP itself is main electro-optical modulator 130.

As described above, one way of dealing with the reduced directivity of main electro-optical modulator 130 at very low frequencies (e.g., less than about 1 GHz) is to use accurate low frequency impedance terminations as stringent calibration standards. Ways of providing improved directivity at low frequencies above the very low frequencies and below the threshold frequency below which the directivity is less than the threshold directivity will be described next. FIG. 11 is a schematic drawing showing another example 400 of a main electro-optical modulator that can be used in embodiments of DDEOPs 100, 102 to provide directivity at low frequencies. Elements of main electro-optical modulator 400 that correspond to elements of main electro-optical modulator 130 are indicated using the same reference numerals and will not be described again in detail. Main electro-optical modulator 400 includes RF through-line 136, modulator optical path 138, an electrical coupled line 406, a termination resistor 408, a capacitor 414, and an electrical low-frequency mixer 420. Low-frequency mixer 420 includes an RF input port 422, and LO input port 424, and a low-frequency IF output port 426.

In main electro-optical modulator 400, modulator optical path 138 is located alongside RF through-line 136, as described above. Electrical coupled line 406 is electrically coupled to RF through-line 136, but is electro-optically isolated from modulator optical path 138. In the example shown, electrical coupled line 406 is located alongside RF through-line 136, opposite modulator optical path 138, and is lengthways substantially coextensive with modulator optical path 138. In another example (not shown), RF through-line 136 is extended lengthways, electrical coupled line 406 is located alongside the extended RF through-line 136 on the opposite side of the electrical through-line from modulator optical path 138, and is lengthways offset from the modulator optical path so that the electrical coupled line and modulator optical path are partially lengthways coextensive or are not lengthways coextensive. A coupled port 410 and an isolated port 412 are located at opposite ends of electrical coupled line 406. Isolated port 412 is offset from coupled port 410 in the direction in which reference light L_{R} propagates through the modulator optical path 138. Isolated port 412 is terminated by termination resistor 408. Coupled port 410 is electrically connected to the RF input port 422 of low-frequency mixer 420. The LO input port 424 of low-frequency mixer 420 is connected to receive a low-frequency local oscillator (LFLO) signal. The low-frequency IF output port 426 of low-frequency mixer 420 outputs a low-frequency reference IF signal to another IF input (not shown) of network analyzer 302 (FIGS. 7 and 8) via low-frequency IF (LFIF) output 416. Capacitor 414 is connected between RF input port 422 and ground.

In an example, a frequency-independent splitter (not shown) splits the LO signal output at the LO output 314 of network analyzer 302 (FIGS. 7 and 8) between LFLO input 428 and LO input 182 (FIGS. 1-4). In another example, a frequency-dependent splitter (not shown) splits the LO signal output at LO output 314 between LFLO input 428 and LO input 182 such that, at high frequencies, all the power of the LO signal goes to LO input 182, and, at low frequencies, the power of the LO signal is divided between LFLO input 428 and LO input 182.

RF through-line 136 and electrical coupled line 406 form a directional electrical coupler that couples a portion of the RF signal propagating in the forward direction along the RF through-line to the RF input port 422 of low-frequency mixer 420. Low-frequency mixer 420 mixes the coupled RF signal output at the coupled port 410 of electrical coupled line 406 with the LFLO signal to generate a low-frequency IF reference signal that is output at low-frequency IF output port 426 to an unused IF input (not shown) of network analyzer 302.

Referring additionally to FIGS. 1 and 2, at low frequencies, the reference IF signal and test IF signal output by optical detectors 170, 174, respectively, are both superpositions of downconverted copies of a true reference RF signal and a true test RF signal. With RF through-line 136 terminated in a short circuit, the reference IF signal and the test IF signal substantially cancel each other, leading to optical detectors 170, 174 outputting the reference IF signal and the test IF signal, respectively, with very small amplitudes. With RF through-line 136 terminated in an open circuit, the reference IF signal and test IF signal reinforce (double) each other, leading to optical detectors 170, 174 outputting respective IF signals with large amplitudes. With RF through-line 136 terminated in a 50Ω load, the amplitude of the true test RF signal is negligible, but, due to the low directivity of main electro-optical modulator 130 at low frequencies, optical detectors 170, 174 output respective IF signals with nearly equal amplitudes. Network analyzer 302 subjects the low-frequency reference IF signal received from LFIF output 416 to complex (real and imaginary part) analog-to-digital conversion to generate respective digital values that represent the amplitude and phase of the true reference RF signal. By subtracting the digital values representing the low-frequency reference IF signal from the DC values representing the (erroneous) test IF signal output by test optical detector 174, the true test IF signal can be calculated. Typical implementations of network analyzers 302 include an arithmetic function capable of performing the needed calculations. Thus, by using a few low frequency calibration standards, the low-frequency IF reference signal output at LFIF output 416, and some simple algebra, the test signal component can be extracted.

To ensure that mixer bounce remains negligible, at least in the interesting high frequency portions of the spectrum, main electro-optical modulator 400 is configured to isolate low-frequency mixer 420 from electrical coupled line 406 at high frequencies. In the example shown in FIG. 8, such isolation is provided by capacitor 414 connected between the RF input port 422 of low-frequency mixer 420 and signal ground. Capacitor 414 has a capacitance sufficient to prevent frequencies at frequencies higher than the low-frequency range from propagating back onto electrical coupled line 406.

FIG. 12 is a schematic drawing showing another example 430 of a main electro-optical modulator that can be used in embodiments of DDEOPs 100, 102 to provide directivity at low frequencies. Elements of main electro-optical modulator 430 that correspond to elements of main electro-optical modulators 130, 400 described above with reference to FIGS. 1 and 11 are indicated using the same reference numerals and will not be described again in detail. Main electro-optical modulator 430 uses a different approach from main electro-optical modulator 400 to isolate low-frequency mixer 420 at frequencies higher than the low-frequency range. Main electro-optical modulator 430 is configured such that coupling between RF through-line 136 and electrical coupled line 406 is very weak. To compensate for the weak coupling, an amplifier 432 is interposed between coupled port 410 and the RF input port 422 of low-frequency mixer 420. Amplifier 432 is configured with a high-frequency rolloff so that it amplifies signals in the low-frequency range, but does not amplify higher frequencies.

FIG. 11 shows termination resistor 408, capacitor 414, and low-frequency mixer 420 as parts of main electro-optical modulator 400, and FIG. 12 shows termination resistor 408, low-frequency mixer 420 and amplifier 432 as parts of main electro-optical modulator 430. In other examples, one or more of these parts are external to the respective main electro-optical modulator 400, 430.

Referring again to FIGS. 1, 2, 5 and 6, in the internal laser light sources 200, 210 of DDEOPs 100, 102, and in the external laser light sources 200, 210 that generate light for input to DDEOPs 100, 102, the common laser 230 of laser light sources 200, 210 generates system light L_{S} at a single wavelength, and beam splitter 240 divides the system light into reference light L_{R} that is output at reference light output 220, and test light L_{T} that is output at the test light output 224. Consequently, in embodiments of DDEOPs 100, 102 in which laser light sources 200, 210 include common laser 230, reference light L_{R} and test light L_{T} have the same wavelength. Reference light L_{R} and test light L_{T} having the same wavelength can be problematic in implementations of DDEOPs 100, 102 having unforeseen reflections at or within one or more of optical couplers 150, 160, main electro-optical modulator 130, and the optical fibers or connectors interconnecting these optical components. Such unwanted reflections contribute coherent superpositions at optical detectors 170, 174 due to the coherence between reference light L_{R} and test light LT. Partial-reflection-induced coherence effects are undesired because they enable even small temperature changes to cause significant fluctuations in the amplitudes of the IF signals and in the DC signals on which the IF signals are superposed. Small temperature changes can cause this effect because they can change the optical path length in meters of fiber by a substantial fraction of a wavelength. Embodiments of DDEOPs 100, 102 in which laser light sources 200, 210 generate reference light L_{R} and test light L_{T} with the same wavelength are prone to this effect since the reference light and the test light originate from the same laser, so that they are automatically mutually coherent. This makes the use of very low return loss (reflection) optical components advisable for implementing such embodiments. Many optical components have return loss specifications of greater than 40 dB, but practical examples of such components have often been found not to meet this specification by at least 20 dB. Consequently, care needs to be exercised in selecting components for implementing these embodiments.

Components having a less stringent return loss specification can be used in embodiments of DDEOPs 100, 102 in which laser light sources 200, 210 generate reference light L_{R} and test light L_{T} at different wavelengths. FIGS. 13 and 14 and 15 are block diagrams showing examples 204, 206, respectively, of laser light source 200, and FIG. 15 is a block diagram showing an example 214 of laser light source 210 that generate reference light L_{R} and test light L_{T} at different wavelengths. Laser light sources 204, 206 are for use as laser light source 200 within or external to DDEOPs, such as DDEOP 100, that need to receive the modulated light, whereas laser light source 214 is for use as laser light source 210 within or external to DDEOPs, such as DDEOP 102, that can receive unmodulated light.

Referring first to FIG. 13, in the example shown, laser light source 204 has a reference light output 220 for connection directly (FIG. 3A) or through optical fiber 112 (FIG. 3B) to the first input port 152 of DDEOP 100, and a test light output 224 for connection directly or through optical fiber 116 to the second input port 162 of DDEOP 100. Laser light source 204 includes a reference laser 520, a test laser 522, an optical combiner 530, and a wavelength-dependent beam splitter 540. In some embodiments, wavelength-dependent beam splitter 540 is implemented using a wavelength diplexer or dichroic splitter. Auxiliary electro-optical modulator 180, described above, is interposed between optical combiner 530 and beam splitter 540. Optical combiner 530 includes a first input 532, a second input 534 and an output 536. Beam splitter 540 includes an input 542, a first output 546 and a second output 548.

The output of reference laser 520 is connected to the first input 532 of optical combiner 530 and the output of test laser 522 is connected to the second input 534 of optical combiner 530. Auxiliary electro-optical modulator 180 is connected between the output 536 of optical combiner 530 and the input 542 of beam splitter 540. The first output 546 of beam splitter 540 is connected to provide reference light L_{R} to the reference light output 220 of laser light source 204. The second output 548 of beam splitter 540 is connected to provide test light L_{T} to the test light output 224 of the laser light source.

Test laser 522 is to generate the test light at a wavelength different from that of the reference light generated by reference laser 520. The difference in wavelength should correspond to a frequency difference larger than twice the highest RF frequency of interest of network analyzer 302 (FIGS. 7 and 8) so that the sidebands generated by modulating the reference light with the RF signal and the LO signal and the sidebands generated by modulating the test light with the RF signal and the LO signal do not overlap in frequency. However, the difference in wavelengths should not be so large that one of the wavelengths (and/or one or more sidebands) is outside the wavelength range in which the properties of the optical components constituting the DDEOPs are substantially wavelength-independent. Reference laser 520 and test laser 522 are unlocked with respect to one another to ensure mutual incoherence. In an example, test laser 522 generates the test light at the same power as the reference light generated by reference laser 520. In another example, test laser 522 generates the test light at a greater power than the reference light generated by reference laser 520. In yet another example, test laser 522 generates the test light at the same power as the reference light generated by reference laser 520, and an optical amplifier (not shown) is interposed between the second output 548 of beam splitter 540 and test light output 224 to increase the power of the test light LT.

Optical combiner 530 combines the reference light generated by reference laser 520 and the test light generated by test laser 522 to form system light LS. Auxiliary electro-optical modulator 180 modulates system light L_{S} in response to the LO signal received at LO input 182. Wavelength-dependent beam splitter 540 divides the modulated system light L_{S} into modulated reference light L_{R} for output to the first input port 152 of DDEOP 100 via reference light output 220, and modulated test light L_{T} for output to the second input port 162 of DDEOP 100 via test light output 224.

The reference light output from the first output 546 of wavelength-dependent beam splitter 540 to reference light output 220 predominantly originates from reference laser 520, and the test light output from the second output 548 of wavelength-dependent beam splitter 540 to test light output 224 predominantly originates from test laser 522. Combining the reference light L_{R} generated by reference laser 520 and the test light L_{T} generated by test laser 522 prior to modulation by auxiliary electro-optical modulator 180 ensures that reference light and test light output by laser light source 204 are identically modulated. Additionally, the use of a single auxiliary electro-optical modulator reduces the power needed for the local oscillator signal and is lower in cost.

Since system light L_{S} received by wavelength-dependent beam splitter 540 is modulated by auxiliary electro-optical modulator 180, each output channel of beam splitter 540 should have a bandwidth greater than twice the highest RF frequency of interest. The above-described frequency difference between reference laser 520 and test laser 522, and the bandwidth of the output channels of beam splitter 540 are each twice the highest RF frequency of interest because auxiliary electro-optical modulator 180 subjects the system light to double-sideband modulation: both the upper sideband and the lower sideband contribute equally to the reference IF signal and the test IF signal.

In an example, wavelength-dependent add-drop multiplexers are commonly used in optical communications. Optical combiner 530 may be implemented using an add-drop multiplexer operating in add mode, and wavelength-dependent beam splitter 540 may be implemented using an add-drop multiplexer operating in drop mode. Reference laser 520 and test laser 522 are typically DFB lasers similar to common laser 230 described above with reference to FIG. 5.

An embodiment of laser light source 204 suitable for generating light for multiple instances of DDEOP 100 has N reference light outputs and N test light outputs, where N is the maximum number of DDEOPs to which laser light source 204 can supply light. An N-way beam splitter (not shown) is interposed between the first output 546 of wavelength-dependent beam splitter 540 and the N reference light outputs, and an N-way beam splitter (not shown) is interposed between the second output 548 of wavelength-dependent beam splitter 540 and the N test light outputs. Additionally, reference laser 520 and test laser 522 are each increased in power by a factor of N. Additionally or alternatively, a respective optical amplifier (not shown) is added between each output 546, 548 of wavelength-dependent beam splitter 540 and the respective the N-way beam splitter, or an optical amplifier (not shown) is added between second output 548 of the wavelength-dependent beam splitter 540 and the N-way beam splitter that splits the test light.

In another dual-laser example of laser light source 200, optical combiner 530 and beam splitter 540 is omitted, and the reference light generated by reference laser 520 and the test light generated by test laser 522 is modulated by respective modulator elements in response to a common local oscillator signal. FIG. 14 shows an example of laser light source 206. In the example shown, laser light source 206 has a reference light output 220 for connection directly (FIG. 3A) or through optical fiber 112 (FIG. 3B) to the first input port 152 of DDEOP 100, and a test light output 224 for connection directly or through optical fiber 116 to 116 second input port 162 of DDEOP 100.

Laser light source 206 includes reference laser 520, test laser 522, and auxiliary electro-optical modulator 180. The reference light generated by reference laser 520 and the test light generated by test laser 522 collectively constitute system light L_{S} that is modulated by auxiliary electro-optical modulator 180. Auxiliary electro-optical modulator 180 includes a reference modulator element 572 and a test modulator element 574. Reference modulator element 572 is interposed between the output of reference laser 520 and reference light output 220. Test modulator element 574 is interposed between the output of test laser 522 and test light output 224. Each modulator element 572, 574 receives the LO signal from LO input 182.

In laser light source 206, the reference light L_{R} output at reference light output 220 originates exclusively from reference laser 520, and the test light L_{T} output at test light output 224 originates exclusively from test laser 522, and differs in wavelength, and may differ in power, from the reference light. This approach eliminates vestiges of test light in the reference light output at reference light output 220, and eliminates vestiges of reference light in the test light output and test light output 224. Any mismatch between the modulation characteristics of modulator elements 572, 574 can be compensated for by a calibration procedure that is routinely performed prior to making measurements using a network analyzer.

An embodiment of laser light source 206 suitable for generating modulated light for multiple instances of DDEOP 100 has N reference light outputs (not shown) and N test light outputs (not shown), where N is the maximum number of DDEOPs to which laser light source 206 can supply light. An N-way beam splitter (not shown) is interposed between reference modulator element 572 and the reference light outputs, and an N-way beam splitter (not shown) is interposed between test modulator element 574 and the test light outputs. Reference laser 520 and test laser 522 are each increased in power by a factor of N. Additionally or alternatively, a respective optical amplifier (not shown) is added between the output of each modulator element 572, 574 and the respective N-way beam splitter, or an optical amplifier (not shown) is added between the output of test modulator element 574 and the N-way beam splitter that splits the test light.

FIG. 15 shows an example of laser light source 214. In the example shown, laser light source 214 has a reference light output 220 for connection directly (FIG. 4A) or through optical fiber 112 (FIG. 4B) to the first input port 152 of DDEOP 102, and a test light output 224 for connection directly or through optical fiber 116 to the second input port 162 of DDEOP 102.

Laser light source 214 includes reference laser 520 and test laser 522. Reference light L_{R} generated by reference laser 520 and test light L_{T} generated by test laser 522 collectively constitute system light LS. The output of reference laser 520 is optically coupled to reference light output 220, and the output of test laser 522 is optically coupled to test light output 224. In laser light source 214, the reference light L_{R} output at reference light output 220 originates exclusively from reference laser 520, and the test light L_{T} output at test light output 224 originates exclusively from test laser 522, and differs in wavelength, and may differ in power, from the reference light.

An embodiment of laser light source 214 suitable for generating unmodulated light for multiple instances of DDEOP 102 has N reference light outputs (not shown) and N test light outputs (not shown), where N is the maximum number of DDEOPs to which laser light source 214 can supply light. An N-way beam splitter (not shown) is interposed between reference laser 520 and the reference light outputs, and an N-way beam splitter (not shown) is interposed between test laser 522 and the test light outputs. Reference laser 520 and test laser 522 are each increased in power by a factor of N. Additionally or alternatively, a respective optical amplifier (not shown) is added between the output of each laser 520, 522 and the respective N-way beam splitter, or an optical amplifier (not shown) is added between the output of test laser 522 and the N-way beam splitter that splits the test light.

Referring additionally to FIGS. 1 and 2, a wavelength difference between reference light L_{R} and test light L_{T} prevents reflections at or within one or more of optical couplers 150, 160, main electro-optical modulator 130, and the optical fibers or connectors interconnecting the optical components from contributing coherent superpositions at optical detectors 170, 174 due to the mutually incoherent lasers 520, 522. This prevents temperature-induced changes in the optical path lengths from undesirably changing the outputs of the optical detectors, and additionally allows DDEOPs 100, 102 to be implemented using optical components having less-stringent return loss specifications.

In DDEOPs 100, 102, the outputs of optical detectors 170, 174 are each split into signal paths labelled IF and DC MON. The signal paths labelled REF IF and TEST IF are electrically connected to reference IF output 176 and test IF output 178, respectively. The signal paths labelled DC MON output DC monitoring signals are optionally used as follows. In laser light sources 204, 206, 214 relative intensity noise (RIN) is uncorrelated between reference laser 520 and test laser 522. The lack of correlation is a source of S-parameter magnitude noise, since S parameters are generated by calculating ratios of digital values that represent the test IF signal and the reference IF signal. With common-laser laser light sources 202, 212 described above with reference to FIGS. 5 and 6, RIN in DDEOPs 100, 102 cancels out when the ratio is calculated since the RIN of common laser 230 appears in both the numerator and the denominator of the calculation. With dual-laser laser light sources 204, 206, 214, however, the RIN in DDEOPs 100, 102 is uncorrelated, However, the respective DC monitoring signals output by reference optical detector 170 and test optical detector 174 provide a measure of the RIN of reference laser 520 and test laser 522, respectively. The DC MON signal generated by reference optical detector 170 can be used to control the intensity of the light generated by test laser 522 (or vice versa) to correlate the RIN in the reference light and the test light. Alternatively, the DC MON signals are used to correct the magnitudes of the reference IF signal and the test IF signal for the RIN.

The electro-optical modulators described herein, i.e., main electro-optical modulators 130, 400, 430, auxiliary electro-optical modulator 180, and modulator elements 184, 186, 572, 574, are described above as being implemented using an intensity modulator, such as a Mach-Zehnder modulator. The electro-optical modulators may alternatively be implemented using a phase modulator. For optical detectors 170, 174 to generate the reference IF signal and test IF signal, the reference light and test light respectively incident thereon should be amplitude modulated (AM). The above-mentioned Mach-Zehnder modulator acts as an amplitude modulator. Phase modulation alone is insufficient, since the photodiodes with which optical detectors 170, 174 are implemented act as optical envelope detectors, and phase modulation leaves the optical envelope unchanged. Thus, in embodiments in which at least one of the electro-optical modulators is implemented using a phase modulator, a reference notch filter (not shown) is interposed between second isolated port 166 and reference optical detector 170, and a test notch filter (not shown) is interposed between first isolated port 156 and test optical detector 174. The notch of the reference notch filter is centered on the wavelength of reference light LR, and the notch of the test notch filter is centered on the wavelength of test light LT.

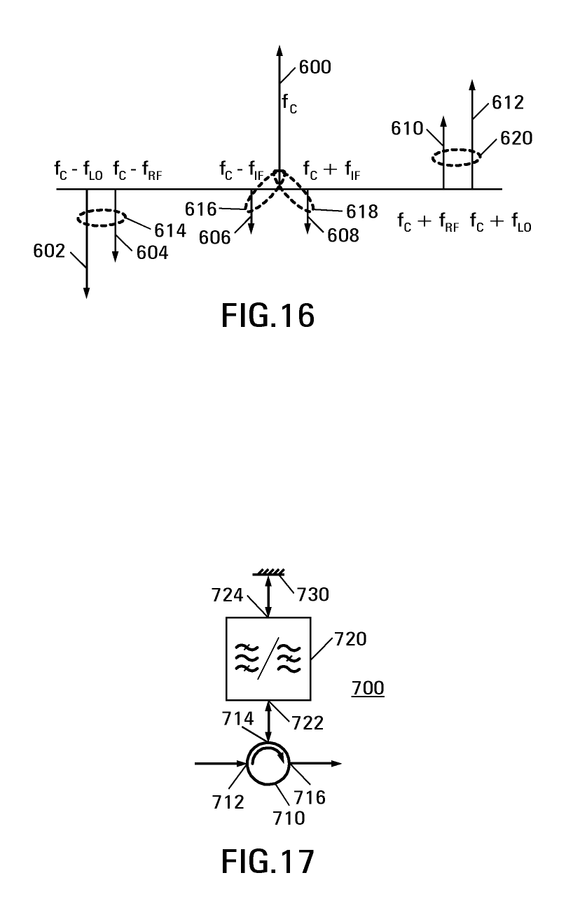

FIG. 16 is a graph showing the seven relevant optical tones that contribute to the reference IF signal generated by reference optical detector 170 in one of the above-described DDEOPs 100, 102 in an example in which reference light L_{R} is phase-modulated by both an LO signal and an RF signal. A similar graph can be drawn for the optical tones contributing to the test IF signal generated by test optical detector 174 in response to test light L_{T} phase-modulated by both an LO and an RF signal.

Referring to FIG. 16, each of the seven optical tones is represented by a respective arrow. One of the seven optical tones is the unmodulated reference light 600 that will be referred to as the carrier and whose frequency will be referred to as carrier frequency f_{C}. The remaining optical tones are a lower sideband (LSB) LO-shifted tone 602 at frequency f_{C}−f_{LO} shifted below carrier frequency f_{C} by the frequency f_{LO} of the LO signal; an LSB RF-shifted tone 604 at frequency f_{C}−f_{RF} shifted below carrier frequency f_{C} by the frequency f_{RF} of the RF signal; an LSB IF-shifted tone 606 at frequency f_{C}−f_{IF} shifted below carrier frequency f_{C} by the frequency f_{IF} of the reference IF signal; an upper sideband (USB) IF-shifted tone 608 at frequency f_{C}+f_{IF} shifted above carrier frequency f_{C} by IF frequency f_{IF}; a USB RF-shifted tone 610 at frequency f_{C}+f_{RF} shifted above carrier frequency f_{C} by RF frequency f_{RF}; and a USB LO-shifted tone 612 at frequency f_{C}+f_{LO} shifted above carrier frequency f_{C} by LO frequency f_{LO}. Upward-pointing arrows, such as the arrow representing unmodulated reference light 600, indicate a sideband phase of 0° while downward-pointing arrows, such as the arrow representing LSB LO-shifted tone 602, indicate a phase of 180°.

LSB IF-shifted tone 606 and USB IF-shifted tone 608 at frequencies shifted relative to the carrier frequency by the frequency of the reference IF signal are the result of the cascade action of the LO and RF modulations. Of the 21 possible pairwise combinations (28 if self-pairing, which is responsible for the DC photocurrent, is included), four pairs of tones can contribute to the reference IF signal generated by optical detector 170. The pairs of tones are a LSB LO-RF tone pair 614, a USB LO-RF tone pair 620, a tone pair 616 composed of LSB IF-shifted tone 606 and carrier 600, and a tone pair 618 composed of USB IF-shifted tone 608 and carrier 600. The contributions of LSB LO-RF tone pair 614 and USB LO-RF tone pair 620 to the reference IF signal exactly cancel the contributions of the IF-shifted and carrier tone pairs 616, 618. Thus, with phase modulation alone, no IF signal is generated by optical detector 170. In the more general large-modulation case, yet more tones must be taken into account, but a similar cancellation results.

Phase modulation can be converted to amplitude modulation by a phase modulation to amplitude modulation converter. One example of a phase modulation to amplitude modulation converter is a notch filter. Implementations of DDEOPs 100, 102 in which at least one of the electro-optical modulators is a phase modulator additionally include a reference notch filter (not shown) between second isolated port 166 and reference optical detector 170, and a test notch filter (not shown) between first isolated port 156 and test optical detector 174. In implementations of DDEOPs 102 in which at least one of the electro-optical modulators is a phase modulator, the reference notch filter (not shown) is located between reference modulator element 184 and reference optical detector 170, and the test notch filter (not shown) is located between test modulator element 186 and test optical detector 174.

In DDEOPs 100, 102 that include or receive light from a common-laser laser light source 200, 210 (FIGS. 5 and 6), the notch filters have notches centered on the carrier frequency of system light L_{S} generated by the common laser to filter out the carrier frequency of system light L_{S} and IF-shifted tones 606, 608 shifted relative to the carrier frequency of the system light by the IF frequency. In DDEOPs 100, 102 that include or receive light from a dual-laser laser light source 200, 210 (FIGS. 13-15), the notch of the reference notch filter is centered on the frequency of the reference light generated by reference laser 520 to filter out the carrier frequency of the reference light and IF-shifted tones 606, 608 shifted relative to the carrier frequency of the reference light by the IF frequency, and the notch of the test notch filter is centered on the carrier frequency of the test light generated by test laser 522 to filter out the carrier frequency of the test light and IF-shifted tones 606, 608 shifted relative to the carrier frequency of the test light by the IF frequency.

In the small-modulation limit, the notch filter preceding reference optical detector 170 reduces the optical tone pairs that contribute to the reference IF signal to only LSB LO-RF tone pair 614 and the USB LO-RF tone pair 620, which add constructively. Filtering out the carrier is effective for phase-to-amplitude modulation conversion as long as J₀(m)< >0, where m is the total (LO+RF) effective FM modulation index and J0 is the 0th order Bessel function of the first kind.

Another example of a phase modulation to amplitude modulation converter is an all-pass filter that reverses the phase relationship between the carrier and the remaining optical tones (including IF-shifted tones 606, 608) either by reversing the phase of the carrier and leaving the phases of the remaining optical tones unchanged, or by leaving the phase of the carrier unchanged and reversing the phases of the remaining optical tones. With such a filter, the above-mentioned cancellation becomes constructive addition, which provides a 6 dB improvement in signal-to-noise ratio compared with filtering out the carrier using a notch filter.

FIG. 17 is a schematic drawing showing an example 700 of an all-pass filter that reverses the phase relationship between the carrier and the remaining optical tones. In the example shown, all-pass filter 700 includes an optical circulator 710, a band filter 720, and a mirror 730. Optical circulator 710 has an input port 712, an input/output port 714 and an output port 716. The term band filter is used herein as a generic term that encompasses a bandpass filter and a bandstop filter, i.e., a notch filter. Band filter 720 includes a first port 722 optically coupled to the input/output port 714 of optical circulator 710, and a second port 724. Mirror 730 is arranged to receive light from the second port 724 of band filter 720 at a normal angle of incidence and is located at a defined distance from second port 724 that provides a 180° optical phase change between light reflected by band filter 720, and light reflected by the mirror.

In an example in which all-pass filter 700 is interposed between second optical coupler 160 and reference optical detector 170, the input port 712 of optical circulator 710 is optically coupled to second isolated port 166, and the output port 716 of the optical circulator is optically coupled to reference optical detector 170.

Modulated reference light that includes the optical tones depicted in FIG. 16 is incident on the input port 712 of optical circulator 710. The modulated reference light passes through optical circulator 710 and is output at input/output port 714 to band filter 720. In an example in which band filter 720 is a notch filter, band filter 720 reflects the carrier, but passes the remaining optical tones to mirror 730. After reflection by mirror 730, the remaining optical tones return through band filter 720 to the first port 722 of the band filter. At first port 722, the phase relationship between the carrier and the remaining optical tones differs by 180° from the phase relationship between the carrier and the remaining optical tones in the modulated reference light. In an example in which band filter 720 is a band-pass filter, band filter 720 reflects the remaining optical tones, but passes the carrier to mirror 730. After reflection by mirror 730, the carrier returns through band filter 720 to the first port 722 of the band filter. At first port 722, the phase relationship between the carrier and the remaining optical tones differs by 180° from the phase relationship between the carrier and the remaining optical tones in the modulated reference light. In both cases, the reference light with the modified phase relationship between the carrier and the remaining optical tones returns to the input/output port 714 of optical circulator 710, passes through the optical circulator, and is output to reference optical detector 170 via output port 716. In reference optical detector 170, the four tone pairs that contribute to the reference IF signal add constructively to generate the reference IF signal with a 6 dB better signal-to-noise ratio than that obtained with a notch filter alone.

All-pass filter 700 would be difficult to implement for use with present-day network analyzers that operate with an IF signal frequency of about 10 MHz. Such a low IF frequency imposes extreme demands on band filter 720, i.e., a bandwidth of about 20 MHz bandwidth and a free spectral range (FSR) extending to hundreds of GHz. However, the need to characterize components operating at ever-higher frequencies may spur the development of network analyzers that operate with a substantially higher IF signal frequency. Embodiments of all-pass filter 700 for use with such network analyzers would be substantially more practical to implement. Again, all-pass filter 700 would be effective for phase-to-amplitude modulation conversion as long as J₀(m)< >0.

Embodiments of DDEOP 100, 102 having internal laser light sources or that are sold bundled with a respective external laser light source, can be described as follows: A dual-directional electro-optic probe, comprising: a laser light source, a main electro-optical modulator, a first optical coupler, a second optical coupler, a reference optical detector, a test optical detector, and an auxiliary electro-optical modulator. The laser light source comprises a reference light output at which the laser light source outputs reference light, and a test light output at which the laser light source outputs test light. The main electro-optical modulator comprises an input radio-frequency (RF) connector, an output RF connector, an RF through-line connected between the input RF connector and the output RF connector, and a modulator optical path extending alongside the RF through-line between a first end and a second end. The first optical coupler includes a first input port, a first through port, and a first output port. The first input port is optically coupled to receive the reference light from the reference light output of the laser light source, and the first through port is optically coupled to the first end of the modulator optical path. The second optical coupler includes a second output port. The second optical coupler includes a second input port, a second through port, and a second output port. The second input port is optically coupled to receive the test light from the test light output of the laser light source, and the second through port is optically coupled to the second end of the modulator optical path. The reference optical detector is optically coupled to the second isolated port to generate a reference intermediate-frequency (IF) electrical signal representing forward RF signal propagation along the RF through-line. The test optical detector is optically coupled to the first isolated port to generate a test IF electrical signal representing reverse RF signal propagation along the RF through-line. The auxiliary electro-optical modulator is to modulate the reference light and the test light in response to a local oscillator signal.

Also disclosed herein, and described above with reference to FIGS. 7 and 8, is a method for measuring properties of a device under test (DUT). The method comprises: providing a reference optical detector, a test optical detector, and a longitudinal, directional electro-optical modulator comprising an RF through-line located alongside a modulator optical path; propagating an RF signal in a forward direction along the RF through-line to the device under test (DUT) as a forward RF signal, a portion of the forward RF signal reflected by the DUT propagating in a reverse direction along the RF through-line as a reverse RF signal; propagating reference light in the forward direction along the modulator optical path to modulate the reference light by the forward RF signal; propagating test light in the reverse direction along the modulator optical path to modulate the test light by the reverse RF signal; additionally modulating the reference light and the test light in response to a local oscillator signal offset in frequency from the RF signal by an intermediate frequency; coupling the reference light after propagating along the modulator optical path to the reference optical detector, where sidebands generated by the forward RF signal and sidebands generated by the local oscillator signal beat to generate a reference IF signal that represents the forward RF signal; and coupling the test light after propagating along the modulator optical path to the test optical detector, where sidebands generated by the reverse RF signal and sidebands generated by the local oscillator signal beat to generate a test IF signal that represents the reverse RF signal.

This disclosure describes the invention in detail using illustrative embodiments. However, the invention defined by the appended claims is not limited to the precise embodiments described.

1. A dual-directional electro-optic probe, comprising:
a main electro-optical modulator, comprising an input radio-frequency (RF) connector, an output RF connector, an RF through-line connected between the input RF connector and the output RF connector, and a modulator optical path extending alongside the RF through-line between a first end and a second end;
a first optical coupler comprising an input port optically coupled to receive the modulated reference light, a through port optically coupled to the first end of the modulator optical path, and a first isolated port;
a second optical coupler comprising an input port, a through port optically coupled to the second end of the modulator optical path, and a second isolated port, the input port optically coupled to receive modulated test light, the modulated test light and the modulated reference light modulated at a local oscillator frequency;
a reference optical detector optically coupled to the second isolated port to generate a reference intermediate-frequency (IF) electrical signal representing forward RF signal propagation along the RF through-line; and
a test optical detector optically coupled to the first isolated port to generate a test IF electrical signal representing reverse RF signal propagation along the RF through-line.

2. The dual-directional electro-optic probe of claim 1, additionally comprising a laser light source, comprising:
a reference light output optically coupled to output the modulated reference light to the reference light input; and
a test light output optically coupled to output the modulated test light to the test light input.

3. The dual-directional electro-optic probe of claim 2, in which the laser light source additionally comprises:
a laser to generate system light; and
a beam splitter to divide the system light between the reference light output and the test light output; and
an auxiliary electro-optical modulator between the laser and the beam splitter.

4. The dual-directional electro-optic probe of claim 2, in which the laser light source additionally comprises:
a reference laser to generate the reference light at a first wavelength;
a test laser to generate the test light at a second wavelength, different from the first wavelength;
an optical combiner to combine the reference light from the reference laser and the test light from the test laser to form system light;
a wavelength-dependent beam splitter to divide the system light into reference light for output at the reference light output and test light for output at the test light output; and
an auxiliary electro-optical modulator interposed between the optical combiner and the wavelength-dependent beam splitter.

5. The dual-directional electro-optic probe of claim 2, in which the laser light source additionally comprises:
a reference laser to generate the reference light at a first wavelength;
a test laser to generate the test light at a second wavelength, different from the first wavelength; and
an auxiliary electro-optical modulator, comprising:
a reference modulator element interposed between the reference laser and the reference light output, and
a test modulator element interposed between the test laser and the test light output.

6. A dual-directional electro-optic probe, comprising:
a main electro-optical modulator, comprising an input radio-frequency (RF) connector, an output RF connector, an RF through-line connected between the input RF connector and the output RF connector, and a modulator optical path extending alongside the RF through-line between a first end and a second end;
a first optical coupler comprising an input port optically coupled to receive reference light, a through port optically coupled to the first end of the modulator optical path, and a first isolated port;
a second optical coupler comprising an input port coupled to receive test light, a through port optically coupled to the second end of the modulator optical path, and a second isolated port;
a reference optical detector optically coupled to the second isolated port to generate a reference intermediate-frequency (IF) electrical signal representing forward RF signal propagation along the RF through-line;
a test optical detector optically coupled to the first isolated port to generate a test IF electrical signal representing reverse RF signal propagation along the RF through-line and
an auxiliary electro-optical modulator comprising a reference modulator element to modulate the reference light, and a test modulator element to modulate the test light, the modulator elements connected to receive a local oscillator signal.

7. The dual-directional electro-optic probe of claim 6, additionally comprising a laser light source, comprising:
a reference light output optically coupled to the reference light input; and
a test light output optically coupled to the test light.

8. The dual-directional electro-optic probe of claim 7, in which the laser light source additionally comprises:
a laser to generate system light; and
a beam splitter to divide the system light between the reference light output and the test light output.

9. The dual-directional electro-optic probe of claim 7, in which the laser light source additionally comprises:
a reference laser to generate the reference light at a first wavelength for output at the reference light output; and
a test laser to generate the test light at a second wavelength, different from the first wavelength, for output at the test light output.

10. The dual-directional electro-optic probe of claim 3, in which:
the RF input is to receive an RF signal at an RF signal frequency; and
the auxiliary electro-optical modulator comprises a high-bandwidth electro-optical modulator connected to receive the local oscillator signal having a local oscillator frequency that differs from the RF signal frequency by the intermediate frequency.

11. The dual-directional electro-optic probe of claim 3, in which:
the RF input is to receive an RF signal having an RF signal frequency; and
the auxiliary electro-optical modulator is connected to receive the local oscillator signal having a local oscillator frequency and an amplitude that overdrives the auxiliary electro-optical modulator to modulate light incident thereon at a harmonic of the local oscillator frequency, the harmonic differing in frequency from the RF signal frequency by the intermediate frequency.

12. The dual-directional electro-optic probe of claim 2, in which:
the RF input is to receive an RF signal having an RF signal frequency; and
the probe additionally comprises a controller to control the laser light source to increase power of the reference light and test light to compensate for a reduction in effective coupling between the RF through-line and the modulator optical path of the main electro-optical modulator as the RF signal frequency increases.

13. The dual-directional electro-optic probe of claim 1, in which each of the first optical coupler and the second optical coupler comprises a respective three-port optical circulator.

14. The dual-directional electro-optic probe of claim 1, in which the main electro-optical modulator comprises a Mach-Zehnder intensity modulator in which optical signals propagating along the modulator optical path are velocity matched to respective RF signals propagating in the same directions along the RF through-line.

15. The dual-directional electro-optic probe of claim 1, in which each of the reference optical detector and the test optical detector comprises a respective photodiode.

16. The dual-directional electro-optic probe of claim 1, in which:
the main electro-optical modulator additionally comprises an electrical coupled line separate from the RF through-line and electrically coupled thereto, the electrical coupled line comprising a coupled port and an isolated port at opposite ends, the electrical coupled line terminated at the isolated port; and
the probe additionally comprises a low-frequency electrical mixer comprising an RF input to receive from the coupled port an RF signal within a low-frequency range in which the main electro-optical modulator has a directivity less than a threshold directivity, a local oscillator input to receive a local oscillator signal, and an IF output to output a reference intermediate-frequency electrical signal representing forward RF signal propagation along the RF through-line in the low-frequency range.

17. The dual-directional electro-optic probe of claim 16, additionally comprising a capacitor shunting the coupled port of the electrical coupled line to signal ground.

18. The dual-directional electro-optic probe of claim 16, in which:
the electrical coupled line is weakly coupled to the RF through-line; and
the probe additionally comprises an amplifier between the coupled port and the RF input of the low-frequency electrical mixer.

19. The dual-directional electro-optic probe of a claim 1, in which:
at least one of electro-optical modulators comprises respective a phase modulator; and
the probe additionally comprises a respective phase modulation to amplitude modulation converter between the first optical coupler and the test optical detector and between the second optical coupler and the reference optical detector.

20. A network analysis system, comprising:
a dual-directional electro-optic probe in accordance with any one of claims 2-9; and
a network analyzer, comprising an RF output electrically connected to the RF input of the probe, an LO output, a reference IF input electrically connected to receive the reference IF signal from the probe, and a test IF input electrically connected to receive the test IF signal from the probe;
in which the LO output of the network analyzer is electrically connected to the auxiliary electro-optical modulator.
